(19) United States
(12) Patent Application Publication
(10) Pub. No.: US 2013/0080858 A1
(43) Pub. Date: Mar. 28, 2013

(54) METHOD OF READING DATA FROM A NON-VOLATILE MEMORY AND DEVICES AND SYSTEMS TO IMPLEMENT SAME

(71) Applicants: Sang Hoon Lee, Yongin-si (KR); Sung-Hwan Bae, Seoul (KR); Jong-Nam Baek, Hwaseong-si (KR); Hyun Seok Kim, Goyang-si (KR); Sung Bin Kim, Seoul (KR)

(72) Inventors: Sang Hoon Lee, Yongin-si (KR); Sung-Hwan Bae, Seoul (KR); Jong-Nam Baek, Hwaseong-si (KR); Hyun Seok Kim, Goyang-si (KR); Sung Bin Kim, Seoul (KR)

(21) Appl. No.: 13/429,326

(22) Filed: Mar. 24, 2012

(30) Foreign Application Priority Data
Sep. 28, 2011 (KR) 10-2011-0098579

(51) Int. Cl. G11C 29/04; G06F 11/16; G06F 12/00

(52) U.S. Cl. 714/773; 711/103; 711/E12.008; 714/E11.054

(57) ABSTRACT

Methods of performing a read retry, including reading a non-volatile memory with new read parameters, and devices for performing such methods are disclosed. The read retry operation and/or subsequent read retry operation may be initiated and/or completed before it is determined that such read retry operation is warranted. For example, a page of a NAND flash memory may be read in a read retry operation with new read voltage levels applied to a word line of the page. For example, a read retry operation may be performed on a target page prior to determining errors of a previous read page of data of the target page are uncorrectable via an ECC operation.

### CROSS-REFERENCE TO RELATED APPLICATIONS

This application claims priority under 35 U.S.C. §119(a) from Korean Patent Application No. 10-2011-0098579 filed on Sep. 28, 2011, the disclosure of which is hereby incorporated by reference in its entirety.

### BACKGROUND

The present invention relates to a semiconductor memory device, and more particularly, to a method of reading data from a non-volatile memory device and apparatuses, such as a memory controller, a non-volatile memory device, and a memory system, therefor.

Memory devices may be volatile memory devices or non-volatile memory devices. Volatile memory devices include dynamic random access memory (DRAM) devices and static random access memory (SRAM) devices. Non-volatile memory devices include flash memory devices, electrically erasable programmable read-only memory (EEPROM) devices, and resistive memory devices.

In certain memory devices, e.g., non-volatile memory devices such as flash memory, as the number of program/erase cycles increases, reliability decreases. An error correction coding (ECC) circuit may be used to correct errors in data read from a flash memory device. When it is difficult or not possible to correct errors using the ECC circuit, a data read retry may be performed.

### SUMMARY

Some embodiments provide a method of reading data from a non-volatile memory device to increase the reliability and/or the read speed of the non-volatile memory device. Also disclosed are a memory controller, a non-volatile memory device, and a memory system including the memory controller and the non-volatile memory device which may perform all or part of the disclosed methods.

In one example, a method of operating a nonvolatile memory includes issuing a first read command that commands the nonvolatile memory to perform a first read of a first page of the nonvolatile memory, receiving a first read page of data resulting from the first read, determining that the first read page of data resulting from the first read has errors that are not to be corrected by an error correction circuit, in response to the determining step, issuing a second read command that commands the non-volatile memory to perform a second read of the first page again with an operating parameter different than an operating parameter used in performing the first read, receiving a second read page of data resulting from the second read; analyzing whether the second read page of data resulting from the second read has errors that are not to be corrected by an error correction circuit, and before the analyzing step is complete, issuing a third read command that commands the non-volatile memory to perform a third read of the first page again with an operating parameter different than an operating parameter used in performing the first read and different from an operating parameter used in performing the second read. Devices are also disclosed which may perform the method and alternatives thereof.

The third read command may be issued before receiving the second read page of data resulting from the second read has been completed, or before receiving any data of the second read page of data resulting from the second read.

The first page may be stored in a first physical page, and the operating parameters may represent a magnitude of a read reference voltage used by the nonvolatile memory to determine memory cell data for each of multiple memory cells of the first physical page.

The nonvolatile memory may be a NAND flash memory, and the operating parameters may represent a magnitude of a read reference voltage applied to a word line of a first physical page of the nonvolatile memory to determine memory cell data for each of multiple memory cells of the first physical page.

The second read command and the third read command may each command the non-volatile flash memory to read the MLC NAND flash memory with two new read reference voltages that are sequentially applied to the word line of the first physical page during the corresponding read operation.

Each of the second read command and third read command may be a read retry command. The read retry command may be unique and be associated with a command code unique for read retry operations. The read retry command may or may not include a value representing the corresponding operating parameter. This corresponding operating parameter may be retrieved from a look-up table (e.g., in a memory controller operating memory or by the non-volatile memory.

The second and third read commands (which may be read retry commands) may not comprise any address information.

The method and devices may determine that a memory array of the nonvolatile memory is not performing a read operation prior to issuing each of the first level set command and second level set command.

A method of operating a NAND flash memory may include a first reading of a first page of the NAND flash memory to obtain a first read page of data, then, prior to completion of an error correction operation on the first page of read data, issuing a read command, the read command causing a second reading of the first page with at least one adjusted read voltage. Devices are also disclosed which may perform these operations.

A method of operating a nonvolatile memory, may include a first reading of a page of the nonvolatile memory with a first read operation parameter to obtain a first read page of data and storing the first read page of data in a first register of the nonvolatile memory, transferring the first read page of data from the first register to a second register of the nonvolatile memory, transferring the first read page of data from the second register to the memory controller, while transferring the first read page of data from the second register to the memory controller, a second reading of the page of data again using a second read operation parameter different from the first read operation parameter. Devices are also disclosed which may perform these operations. The nonvolatile memory may be a NAND flash memory and the page may be stored in a first physical page of the NAND flash memory. The method may also include applying the first read reference voltage to a word line of the first physical page during the first reading to determine memory cell data for each of multiple memory cells of the first physical page, and applying the second read reference voltage to the word line of the first physical page during the second reading to determine memory cell data for each of multiple memory cells of the first physical page.

The nonvolatile memory may be a multi-level cell (MLC) NAND flash memory and the page may be stored in a first physical page of the NAND flash memory, and the method may include applying a first set of read reference voltages including the first read reference voltage to a word line of the first physical page during the first reading to determine memory cell data for each of multiple memory cells of the first physical page; and applying a second set of read reference voltages including the second read reference voltage to a word line of the first physical page during the second reading to determine memory cell data for each of multiple memory cells of the first physical page, wherein the second set of read reference voltages are different from the first set of read reference voltages.

The read retry command may be a unique command dedicated to read retries. The read retry command may instruct the nonvolatile memory device to perform the second reading. The read retry command may include a value representing updated read operation parameter(s), a separate level setting command may be issued to provide updated read operation parameter(s) or the non-volatile memory may internally access information to determine updated read operation parameter(s). The read retry command may not comprise any address information in some examples.

Some example devices and methods may include a first reading of a first page of the NAND flash memory to obtain a first read page of data, then, prior to completion of an error correction operation on the first read page of data, issuing a read command, the read command causing a second reading of the first page with at least one adjusted read voltage.

The read command may be issued before receiving all and/or any of the first read page of data resulting from the first reading.

According to some aspects, a nonvolatile memory may include a memory array including a first physical page, a first data register, a second data register, and a control circuit, configured to perform a first reading of a page to obtain a first read page, to store the first read page into the first data register, transfer the first read page of data resulting from the first reading from the first data register to the second data register, to perform a second reading of the page when the first read page of data resulting from the first reading is stored in the second data register, and to transfer the page of data resulting from the first reading from the second data register to an external source.

According to some aspects, a nonvolatile memory device may include a memory array, a command circuit configured to receive a read command and to initiate a read operation of the memory array in response to the read command, a control circuit configured to assert a first R/B (ready busy) flag to indicate the nonvolatile memory cannot accept additional commands and being responsive to the read operation to assert a second R/B flag to indicate a status of the memory array, and a data buffer configured to output data from the nonvolatile memory when the second R/B flag indicates a busy status of the memory array in response to the read operation.

The control circuit may be responsive to a read status command received from an external memory controller to assert the first R/B flag and the second R/B flag in response.

A memory controller configured to operate a NAND flash memory may include an interface, an error correction coding circuit configured analyze a page of data received over the interface to correct bit errors of the page and to determine if the page of data has an uncorrectable error, and a command circuit configured to generate commands and output the same to the interface, including a first read command to cause a first read of a first page of the NAND flash memory and to receive a first read page over the interface resulting from the first read. The error correction coding circuit may be configured to determine if first read page has an uncorrectable error, and the command circuit may be configured to issue a second read command, prior to completion of a determination operation by the error correction coding circuit to determine whether the first read page of data has an uncorrectable error, the second read command causing a second read of the first page with at least one adjusted read voltage.

The command circuit may be configured to issue the second read command before all of the first read page of data is received over the interface. The command circuit may be configured to issue the second read command before any of the first read page is received over the interface. The second read command may be a read retry command.

Devices, such as a memory card, may include a non-volatile memory device comprising a memory cell array which comprises a plurality of pages storing data and an access circuit which comprises a first register temporarily storing data read from the memory cell array in a read operation and a second register receiving data from the cache register and storing the data, a card interface configured to communicate with a host, and a memory controller interfaces between the non-volatile memory device and the card interface, wherein the memory controller is configured to transmit to the non-volatile memory a first read command to read data from a target page among a plurality of pages in the non-volatile memory device, and to transmit a second read command to the non-volatile memory to read data from the target page, and wherein the memory controller is configured to receive data that has been read in response to the first read command while the non-volatile memory device is reading data from the target page in response to the second read command.

A method of reading data from a non-volatile memory may include receiving data read from a target page of a non-volatile memory device and performing error correction coding on the data, setting a read voltage level and outputting a read retry command for reading data from the target page to the non-volatile memory device when an R/B signal is in a ready state and the error correction coding fails, receiving data that has been read in a previous read operation and temporarily stored in the second register from the non-volatile memory device and performing error correction coding on the data, and repeating these setting and receiving data operations until the error correction coding is completed and when the error correction coding is completed, resetting the non-volatile memory device and terminating the read operation. The operation of receiving data may be performed while the non-volatile memory device is reading data of the target page from the memory cell array in response to the read retry command.

The R/B signal may comprise a host R/B signal output to a first input/output pin and an array R/B signal output to a second input/output pin.

The setting operation may include monitoring the host R/B signal and the array R/B signal, and setting the read voltage level and outputting the read retry command for reading data from the target page to the non-volatile memory device when both of the host R/B signal and the array R/B signal are in the ready state.

The setting operation may include storing a plurality of predetermined values for the read voltage level, setting read voltage level(s) to one or more of the predetermined values based on the read retry command, and reading data from the target page using the newly set read voltage level(s).

The total read retry operation may be terminated and determined as failed when a certain amount of repeating of the setting and receiving operations has been attempted, such as when all of the predetermined values for the read voltage level have been used in the read retry operations.

The method may also include controlling the non-volatile memory device to read data from the target page and temporarily store it using the read retry command, and receiving the data temporarily stored in the previous read operation using the read retry command and performing the error correction coding on the data.

A computer readable recording medium may store a program to execute the methods disclosed herein.

A method may comprise outputting a normal read command for reading data from a target page to the non-volatile memory device, setting a read voltage level and outputting a read retry command for reading data from the target page to the non-volatile memory device when an R/B signal is in a ready mode without an error check on the data read in response to the normal read command, receiving data that has been read and temporarily stored in a previous read operation from the non-volatile memory device and performing error correction coding on the data, and repeating setting and receiving operations until the error correction coding is completed and when the error correction coding is completed, resetting the non-volatile memory device and terminating the read operation. At least part of or all of the receiving operation may be performed when the non-volatile memory device reads data of the target page from the memory cell array in response to the read retry command.

A memory controller may include a central processing unit configured to transmit a first read command for reading data from a target page among a plurality of pages in a non-volatile memory device to the non-volatile memory device in response to a data read command received from a host, to monitor a status signal of the non-volatile memory device, and to set a read voltage level and transmit a second read command for the target page to the non-volatile memory device when the status signal is in a ready state, and an error correction coding (ECC) block configured to receive data of the target page from the non-volatile memory device and perform ECC, wherein the memory controller may be configured to receive data that has been read in response to the first read command and stored in a data register of the non-volatile memory device and/or configured to perform ECC on the data while the non-volatile memory device is reading data from the target page in response to the second read command.

The memory controller may include a read level table configured to store a plurality of predetermined values for the read voltage level.

The central processing unit may be configured to determine the error correction coding as failed when the data of the target page is not read in a read retry repeatedly performed based on all of the predetermined values stored in the read level table and controls the read retry to be terminated.

The first read command and the second read command may be a normal read command or a unique read retry command.

The status signal may comprise a host R/B signal output to a first input/output pin and an array R/B signal output to a second input/output pin, and the central processing unit may cause a read retry to be performed when both of the host R/B signal and the array R/B signal are in the ready state.

A memory system may comprise a non-volatile memory device comprising a memory cell array which comprises a plurality of pages storing data and an access circuit which comprises a cache register temporarily storing data read from the memory cell array in a read operation and a data register receiving data from the cache register and storing the data, and a memory controller configured to control an operation of the non-volatile memory device. The memory controller may transmit a first read command for reading data from a target page among a plurality of pages in the non-volatile memory device to the non-volatile memory device in response to a data read command received from a host, monitor a state signal of the non-volatile memory device, and set a read voltage level and transmits a second read command for the target page to the non-volatile memory device when the state signal is in a ready state. The non-volatile memory device may read data from the target page in response to the second read command while the memory controller receives data that has been read in response to the first read command and stored in a data register of the non-volatile memory device and/or while the memory controller performs error correction coding on the data.

The memory system, memory controller and/or non-volatile memory may be configured to perform the methods described herein.

The memory system may be implemented as a multi-chip package comprising a non-volatile memory device and a memory controller as described herein.

A memory card may include a non-volatile memory device comprising a memory cell array which comprises a plurality of pages storing data and an access circuit which comprises a cache register temporarily storing data read from the memory cell array in a read operation and a data register receiving data from the cache register and storing the data, a card interface configured to communicate a host, and a memory controller configured to control an interface between the non-volatile memory device and the card interface. The memory controller may transmit a first read command for reading data from a target page among a plurality of pages in the non-volatile memory device to the non-volatile memory device in response to a data read command received from a host, monitor a state signal of the non-volatile memory device, and set a read voltage level and transmit a second read command for the target page to the non-volatile memory device when the state signal is in a ready state. While non-volatile memory device is reading data from the target page in response to the second read command, the memory controller may receive data that has been read in response to the first read command and stored in a data register of the non-volatile memory device and/or perform error correction coding on the data.

The memory card may be a multimedia card (MMC), a secure digital (SD) card or an USB flash drive.

A portable communication system may include a flash memory device comprising a memory cell array which comprises a plurality of pages storing data and an access circuit which comprises a cache register temporarily storing data read from the memory cell array in a read operation and a data register receiving data from the cache register and storing the data, a memory controller configured to control an operation of the flash memory device, and a display device configured to display data output from the flash memory device according to a control of the memory controller. The memory controller may transmit a first read command for reading data from a target page among a plurality of pages in the memory device to the memory device in response to a data read command received from a host, monitors a state signal of the memory device, set a read voltage level and transmit a second read command for the target page to the memory device when the state signal is in a ready state. While the memory device is reading data from the target page in response to the second read command, the memory controller may receive data that has been read in response to the first read command and stored in a data register of the memory device and/or may perform error correction coding on the data.

A three-dimensional (3D) memory system may comprise a three-dimensional flash memory device comprising a memory cell array which comprises a plurality of layers including a plurality of pages storing data and an access circuit which comprises a cache register temporarily storing data read from the memory cell array in a read operation and a data register receiving data from the cache register and storing the data, and a memory controller configured to control an operation of the three-dimensional flash memory device. The memory controller may transmit a first read command for reading data from a target page among a plurality of pages in the memory device to the memory device in response to a data read command received from a host, monitor a state signal of the memory device, set a read voltage level and transmit a second read command for the target page to the memory device when the state signal is in a ready state. While the memory device is reading data from the target page in response to the second read command, the memory controller may receive data that has been read in response to the first read command and stored in a data register of the memory device and/or may perform error correction coding on the data.

A solid state drive (SSD) may include a memory device comprising a memory cell array which comprises a plurality of pages storing data and an access circuit which comprises a cache register temporarily storing data read from the memory cell array in a read operation and a data register receiving data from the cache register and storing the data, and a memory controller configured to control an operation of the three-dimensional flash memory device. The memory controller may transmit a first read command for reading data from a target page among a plurality of pages in the memory device to the memory device in response to a data read command received from a host, monitor a state signal of the memory device, set a read voltage level and transmit a second read command for the target page to the memory device when the state signal is in a ready state. While the memory device is reading data from the target page in response to the second read command, the memory controller may receive data that has been read in response to the first read command and stored in a data register of the memory device and/or may perform error correction coding on the data.

A non-volatile memory device may include a memory cell array comprising a plurality of pages configured to store data; and an access circuit configured to, in response to a first externally received read command, read data from a target page among the plurality of pages using a first read voltage and store the read data in a cache register, store the data in the cache register in a data register, and in response to a second read command, read data again from the target page using a second read voltage and store the read data in the cache register. While the data is read again from the target page using a second (adjusted) read voltage and stored in the cache register in response to the second read command, the data in the data register may be output to a source external to the non-volatile memory.

Non-volatile memory devices disclosed herein may comprise one or plural semiconductor chips.

The non-volatile memory may automatically initiate a third read of the data from the target page with a third (adjusted) read voltage.

The adjusting the read voltages may be responsive to an external command with new voltage level information, or may be automatically performed by the non-volatile memory without new level information provided by an external source.

Memory systems may include non-volatile memories disclosed herein in combination with a memory controller. Memory systems may include memory controllers disclosed herein in combination with non-volatile memories.

A method may comprise reading data from a target page in a memory cell array of a non-volatile memory array using a first read voltage and storing the read data in a cache register of the non-volatile memory array, storing the data in the cache register in a data register, and reading data again from the target page using a second read voltage and storing the read data in the cache register, wherein while the reading is performed, the data in the data register may be output externally and/or error correction may be performed on the data. The error correction may include detecting whether there are any errors, whether such errors are correctable and/or correcting any erroneous bits of the data.

The reading operation may comprise storing a first retry data temporarily stored in the cache register in the data register, reading data again from the target page in the memory cell array using a reset read voltage and storing the read data in the cache register as a second retry data, and outputting the first retry data in the data register to an external device.

A method of reading data from a non-volatile memory device may include outputting a first read command to a non-volatile memory device for reading data from a target page of a memory cell array of the non-volatile memory device, setting a read level, transmitting a second read command for reading data again from the target page of the non-volatile memory device; and receiving data read from the target page and stored in the data register in response to the first read command and performing error correction coding on the data. Receiving data read from the target page and stored in the data register in operation may be performed in parallel with an operation of the non-volatile memory device of reading and storing data of the target page in the cache register in response to the second read command.

The method may include outputting a normal read command prior to the steps noted above and triggering the steps noted above when the normal read command results in read data including errors uncorrectable by an ECC operation.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a host and a memory system according to some embodiments;

FIG. 2 is a detailed block diagram of a memory controller illustrated in FIG. 1;

FIG. 3 is a schematic diagram showing the structure of a non-volatile memory device, such as that illustrated in FIG. 1 according to some embodiments;

FIG. 4 is a detailed block diagram of a non-volatile memory device, such as that illustrated in FIG. 1;

FIG. 5A is a detailed circuit diagram of an exemplary memory cell array, such as that illustrated in FIG. 2 according to some embodiments;

FIG. 5B is a detailed circuit diagram of an exemplary memory cell array, such as that illustrated in FIG. 2 according to other embodiments;

FIG. 6A is a diagram for explaining a read retry operation in the memory system illustrated in FIG. 1; FIG. 6B is a diagram for explaining a level set operation affecting multiple operation parameters of a read retry operation.

FIGS. 7A through 7D are timing diagrams of a read retry operation, which may be performed by the memory system illustrated in FIG. 1;

FIG. 8 is a diagram showing exemplary command signals, which may be sent by the memory controller to the non-volatile memory device illustrated in FIG. 1 according to some embodiments;

FIG. 9 is a diagram showing exemplary status signals input/output between the non-volatile memory device and the memory controller, such as those illustrated in FIG. 1 according to some embodiments;

FIG. 10A is a timing diagram of the operation of a memory system, such as that illustrated in FIG. 1 according to some embodiments;

FIG. 10B is a diagram showing the operation of a memory system according to the embodiments illustrated in FIG. 10A;

FIG. 11A is a timing diagram of the operation of the memory system, such as that illustrated in FIG. 1 according to other embodiments;

FIG. 11B is a diagram showing the operation of the memory system according to the embodiments illustrated in FIG. 11A;

FIG. 12A is a timing diagram of the operation of the memory system illustrated in FIG. 1 according to further embodiments;

FIG. 12B is a diagram showing the operation of the memory system according to the embodiments illustrated in FIG. 12A;

FIG. 13 is a flowchart of a method of controlling data reading using the memory system illustrated in FIG. 1 according to some embodiments;

FIG. 14 is a flowchart of a method of controlling data reading using the memory system illustrated in FIG. 1 according to other embodiments;

FIG. 15 is a data processing system, which includes the memory system shown in FIG. 1, according to an exemplary embodiment;

FIG. 16 is a data processing system, which includes the memory system shown in FIG. 1, according to another exemplary embodiment;

FIG. 17 is a data processing system, which includes the memory system shown in FIG. 1, according to still another exemplary embodiment.

FIG. 18 is a data processing system, which includes the memory system shown in FIG. 1, according to still another exemplary embodiment;

FIG. 19 is a data processing system, which includes the memory system shown in FIG. 1, according to still another exemplary embodiment; and

FIG. 20 is a block diagram of a data storage device 1000 including the data processing system 900 illustrated in FIG. 19.

### DETAILED DESCRIPTION OF THE EMBODIMENTS

Exemplary embodiments will be described more fully hereinafter with reference to the accompanying drawings. This invention may, however, be embodied in many different forms and should not be construed as limited to the exemplary embodiments set forth herein. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that terms such as “comprises,” “comprising,” “includes,” “including,” “made of,” “have,” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

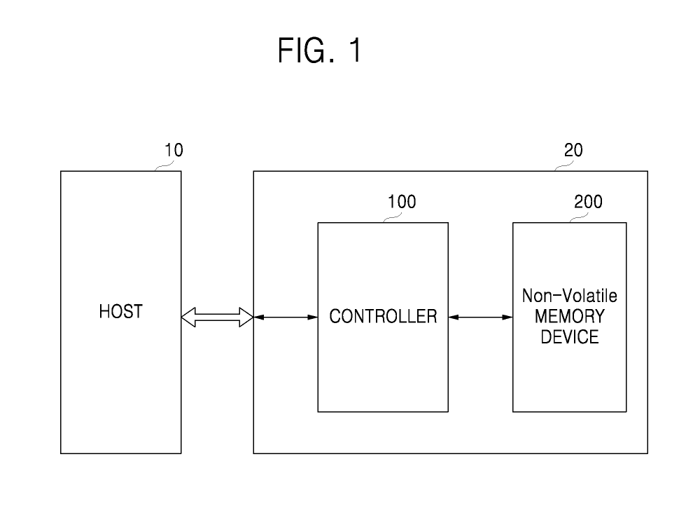

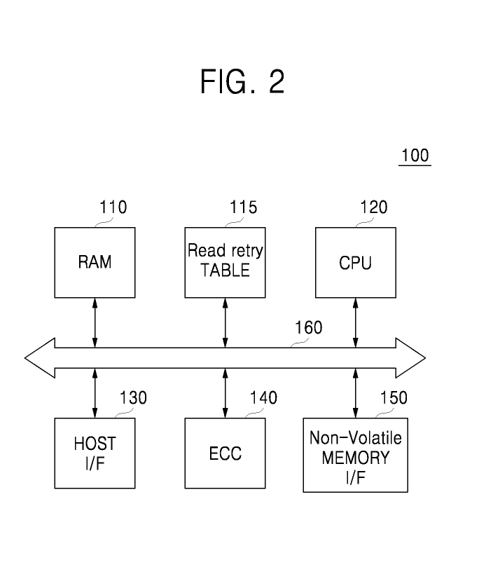

FIG. 1 is a block diagram of a host 10 and a memory system 20 according to some embodiments. FIG. 2 is a detailed block diagram of memory controller 100 illustrated in FIG. 1.

Referring to FIG. 1, the memory system 20 connected with the host 10 includes the memory controller 100 and a non-volatile memory device 200. The memory system 20 may be any system that includes a non-volatile memory.

Referring to FIG. 2, the memory controller 100 includes a memory device (e.g., a random access memory (RAM)) 110, a read retry table 115, a central processing unit (CPU) 120, a host interface 130, an error correction coding (ECC) circuit 140, and a non-volatile memory interface 150.

The memory controller 100 generates an address and a command (e.g., a program command, a read command, or an erase command) to control the operation (e.g., the program, read or erase operation) of the non-volatile memory device (e.g., a flash memory device) 200. Within the nonvolatile memory device 200, the program operation and the read operation may be performed in units of pages and the erase operation may be performed in units of blocks. A block may be the minimal sized unit of erase (i.e., one portion of a block may not be erased without erasing all portions of this block). A block may comprise a plurality of physical pages, each of which may store one or more data pages. Each physical page may include a plurality of memory cells operably connected to a respective word line. For example, a word line, when activated, may apply a voltage to gates of memory cell transistors (e.g., EEPROM transistor cells). The word line may connect to or be formed (at least in part) of the gates of the memory cell transistors. It should be noted that the term “page” may have several meanings. As used in this application, “page” generally will refer to a data page stored in the nonvolatile memory, such as an LSB (lease significant bit) page or an MSB (most significant bit) page stored in an MLC NAND flash memory. The phrase “physical page” references the physical structure storing the data.

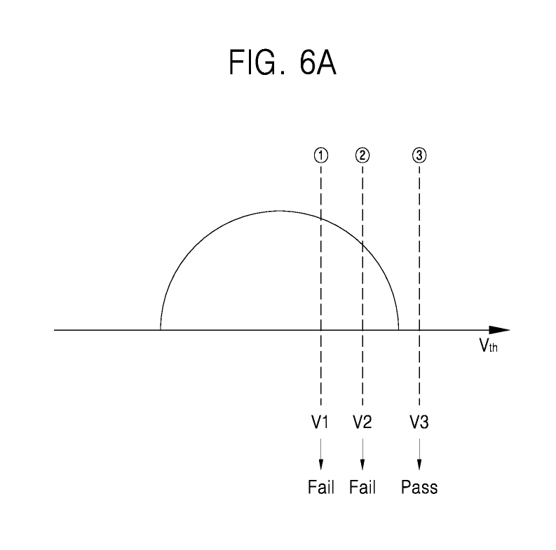

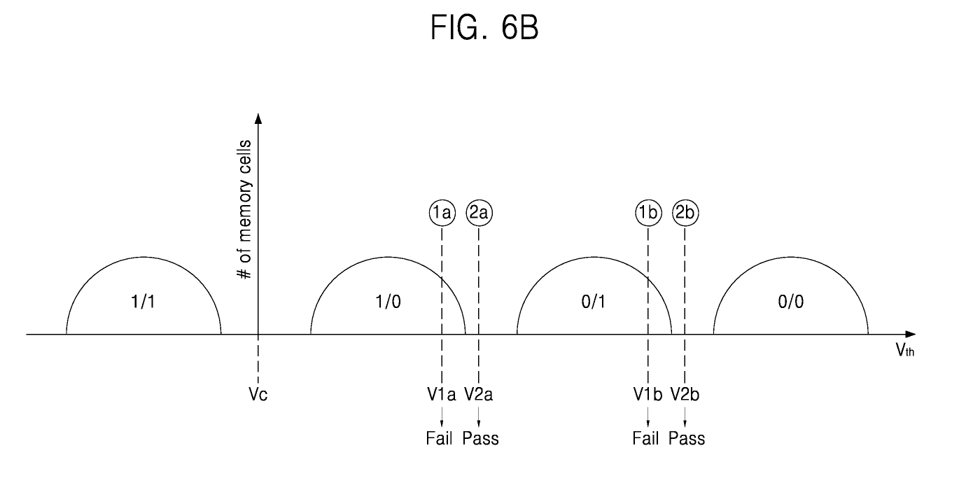

The memory controller 100 sends a command for controlling the operation of the non-volatile memory device 200 to the non-volatile memory device 200. The command may be a command that will be explained with reference to FIG. 6A.

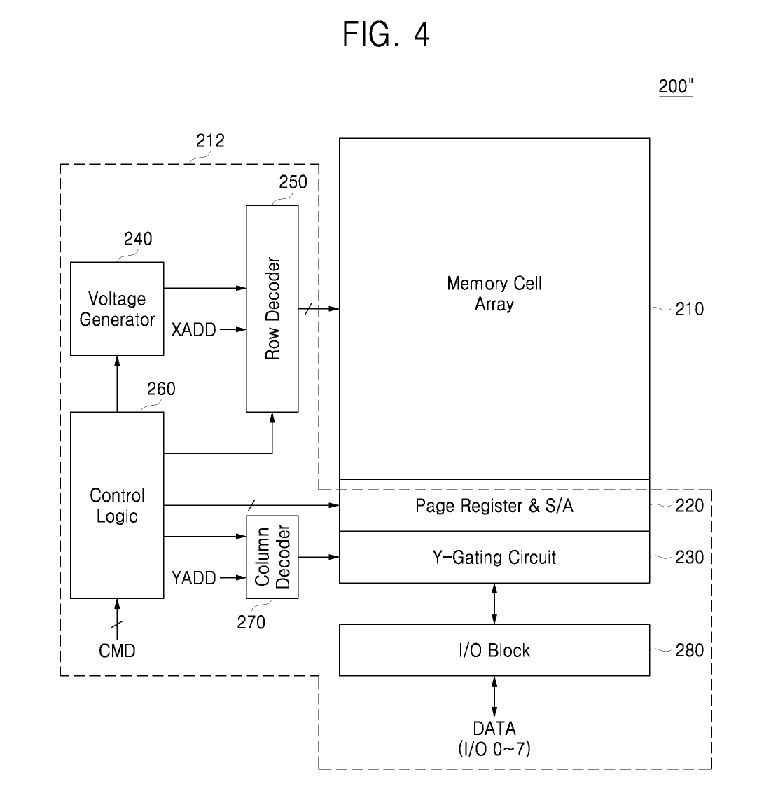

The non-volatile memory device 200 performs an operation in response to the command and may transmit an operation result to the memory controller 100. The non-volatile memory device 200 is connected with the memory controller 100 through one or more input/output (I/O) pins through which the command, data, address, a status signal, etc. may be output and/or input. FIG. 4 shows that eight I/O pins I/O0 through I/O7 are provided, but the number of I/O pins is not restricted to eight (8). In addition, it should be noted that the term “pin” as used herein does not require an elongated conductive element, but may comprise any terminal suitable for input and/or output, such as a solder bump (e.g., a solder ball), a chip pad, a package pad, etc. For the sake of convenience, the following description will focus on the read operation.

The memory controller 100 and the non-volatile memory device 200 may be separately packaged into different packages, respectively, and these different packages may be encapsulated together into a single package (e.g., in a package on package configuration) or the memory controller 100 and the non-volatile memory device 200 may be stacked chips or mounted together on a printed circuit board substrate and then packaged together into a single package.

The memory device 110 may be used as an operation memory of the CPU 120. The memory device 110 may be implemented by dynamic RAM (DRAM) or static RAM (SRAM).

The read retry table 115 stores information about a read level in the read operation on the non-volatile memory device 200. The information about the read level may be information about a read voltage used to read the state of memory cells during the read operation. For example, the read level may cause a particular read voltage to be applied by the non-volatile memory to the word line of a page desired to be read—a different read level would result in a different read voltage being applied to the word line in a subsequent read operation (e.g., a read retry operation). A difference between a new read level and an old read level may be stored in the read retry table 115. The read retry table 115 may be implemented in a separate memory (e.g., a register) within the memory controller 100 or may be implemented in the memory device 110. An exemplary read retry table 115 will be described in detail later.

The host interface 130 interfaces data between the host 10 and the memory controller 100 according to a protocol of the host 10 connected with the memory system 20.

The ECC circuit 140 detects and corrects errors in data read from the non-volatile memory device 200. The non-volatile memory interface 150 interfaces between the non-volatile memory device 200 and the memory controller 100 to communicate data, address, commands, and/or status signals, etc. between the non-volatile memory device 200 and the memory controller 100.

The CPU 120 controls data transmission among the memory device 110, the host interface 130, the ECC circuit 140, and the non-volatile memory interface 150 through a bus 160.

The memory system 20 may be a memory card, a memory drive, a solid state disk or solid state drive (SSD), or a managed NAND. The memory card may be a secure digital (SD) card or a multimedia card (MMC). The memory drive may be a universal serial bus (USB) flash drive or a memory stick. The managed NAND may be a controlled-embedded NAND chip.

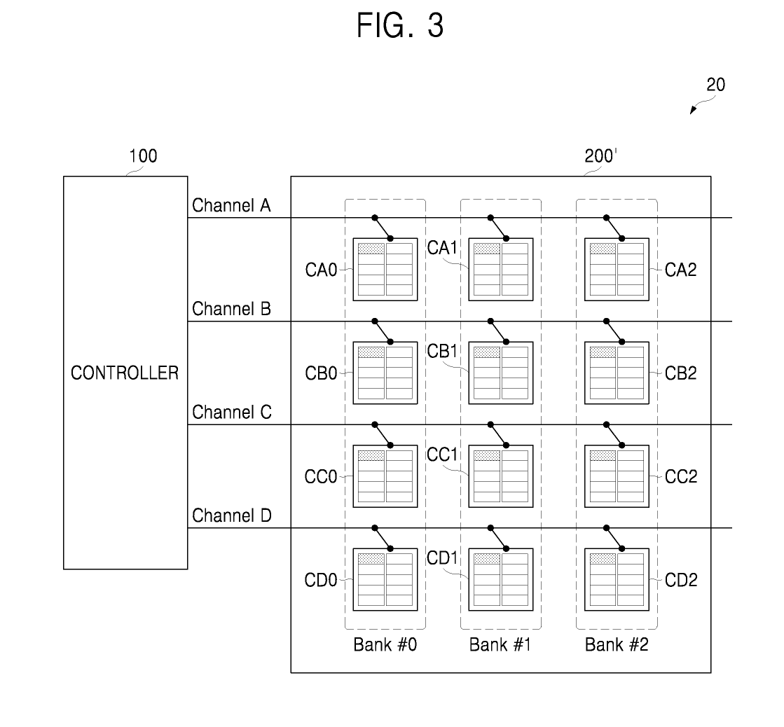

FIG. 3 is a schematic diagram showing details of a non-volatile memory device 200′, which may be the non-volatile memory device 200 illustrated in FIG. 1 according to some embodiments of the present invention.

Referring to FIG. 3, the non-volatile memory device 200′ may include a plurality of memory elements. FIG. 3 shows the embodiments in which the non-volatile memory device 200′ has a 4-channel 3-bank hardware structure, but the present invention is not restricted to the current embodiments.

In the memory system 20, the memory controller 100 and the non-volatile memory device 200′ are connected through four channels A, B, C, and D. Three flash memory elements CA0 through CA2, CB0 through CB2, CC0 through CC2, or CD0 through CD2 are connected to a corresponding one of the channels A, B, C, and D. However, it is apparent that the numbers of channels and banks may be changed. Each memory element may be a memory chip.

Each bank may comprise a group of memory elements addressable with a same offset in different channels.

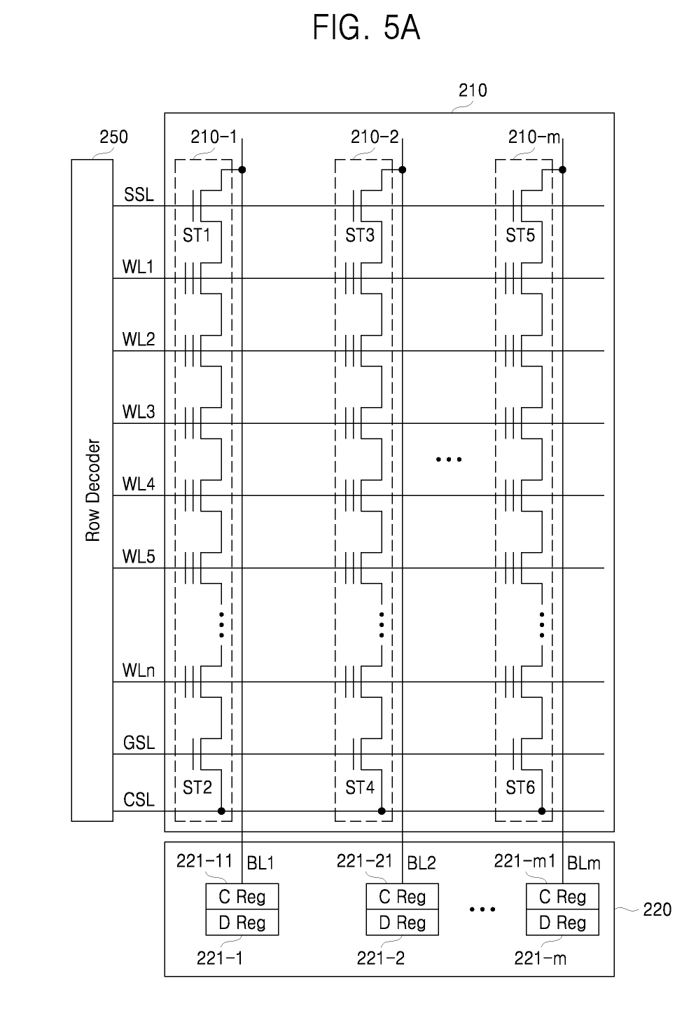

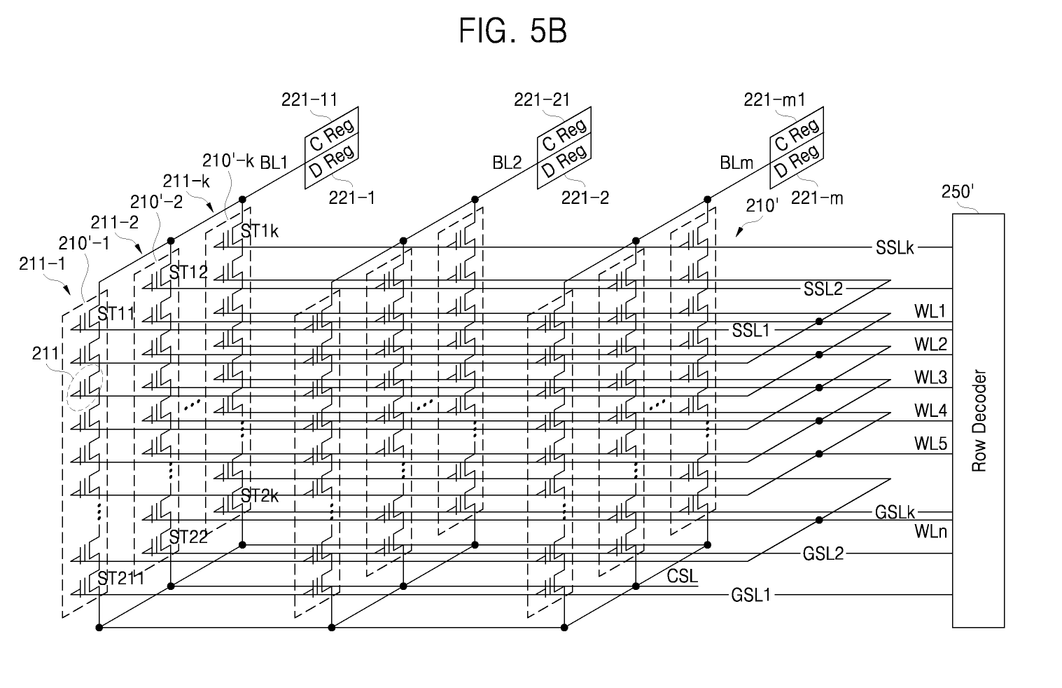

FIG. 4 is a detailed block diagram showing details of a non-volatile memory device 200″, which may be the non-volatile memory device 200 illustrated in FIG. 1. Alternatively, each of the memory elements CA0 through CD2 shown in FIG. 3 may constitute a non-volatile memory device 200″ of FIG. 4 (and the entire collection of CA0 through CD2 of multiple non-volatile memory devices 200″ may be the non-volatile memory device 200 of FIG. 1). FIG. 5A is a circuit diagram showing exemplary details of memory cell array 210 and of the page register and sense amplifier 220 illustrated in FIG. 4 according to some embodiments. FIG. 5B is a circuit diagram showing an alternative example of the memory cell array 210 and of the page register and sense amplifier 220 illustrated in FIG. 4 according to other embodiments.

Referring to FIG. 4, the non-volatile memory device 200 includes a memory cell array 210 and an access circuit 212. Each of the memory elements CA0 through CD2 in the non-volatile memory device 200′, shown in FIG. 3, may have the structure shown in FIG. 4.

As mentioned above, the program operation and the read operation may be performed in units of pages and the erase operation may be performed in units of memory blocks. A memory block may comprise a plurality of pages.

The memory controller 100 and the non-volatile memory device 200′ of FIG. 3 are connected to each other through a plurality of channels, each channel being connected to a subset of the plurality of flash memory elements CA0 through CD2 as shown.

As shown in FIG. 5A, the memory cell array 210 includes a plurality of NAND memory cell string 210-1, 210-2 . . . 210-m connected to a respective bit line, BL1, BL2 . . . BLm. As is known, each NAND memory cell string 210-1, 210-2 . . . 210-m includes a plurality of non-volatile memory cells connected in series, which are interposed between two select transistors. For example, NAND memory cell string 210-1 includes a series connected non-volatile memory cells sandwiched between select transistor ST1 and select transistor ST2. Select transistors ST3, ST4, ST5 and ST6 are connected in a similar fashion with respect to NAND memory cell strings 210-2 and 210-m as shown. Gates of string select transistors ST1, ST3 and ST5 are connected to string select line SSL while gates of ground select transistors ST2, ST4 and ST6 are connected to a ground select line GSL. Drains of string select transistors ST1, ST3 and ST5 are connected to a respective bit line BL1, BL2 and BLm, while sources of ground select transistors ST2, ST4 and ST6 are connected to a common source line CSL. Gates of the non-volatile memory cells are connected to word lines (one of WL1 to WLn in FIG. 5A). NAND memory cell strings may be laid out on one plane or in a two dimensional layer, as illustrated in FIG. 5A. Further details of exemplary structure and operation of a NAND flash memory may be found in U.S. Pat. No. 5,473,563 which is incorporated by reference in its entirety.

Alternatively, the memory cell array 210 may be implemented in three dimensions, as illustrated in FIG. 5B, using a wafer stack, a chip stack, or a cell stack. Details of exemplary structure and operation of a 3D NAND may be found in U.S. Pat. No. 7,679,133 which is hereby incorporated by reference in its entirety.

Each of the non-volatile memory cells included in the NAND memory cell string may be implemented by a flash electrically erasable programmable read-only memory (EEPROM) cell that can store one or more bits. Accordingly, each non-volatile memory cell may be implemented by a NAND flash memory cell, e.g., a single level cell (SLC) storing one bit or a multilevel cell (MLC) storing at least two bits.

The access circuit 212 accesses the memory cell array 210 in response to a command (or a command set) and an address, which are received from an outside, e.g., the memory controller 100, to perform a data access operation, e.g., the program operation, the read operation, or the erase operation.

The access circuit 212 includes a voltage generator 240, a row decoder 250, a control logic 260, a column decoder 270, a page register and sense amplifier (S/A) block 220, a Y-gating circuit 230, and an I/O block 280.

The voltage generator 240 generates voltages necessary for the data access operation in response to a control code generated by the control logic 260.

In response to the control code, the voltage generator 240 generates a program voltage and a program verify voltage for the program operation, a read voltage and a pass voltage for the read operation, and an erase voltage and an erase verify voltage for the erase operation and outputs the voltages to the row decoder 250.

The control logic 260 controls the overall operation of the access circuit 212 in response to a control signal CMD received from the memory controller 100. For instance, the control logic 260 may control memory read status information to be sensed and data to be output to the memory controller 100 during the read operation.

In response to the command CMD, the control logic 260 may also transmit data stored in a data register as read data to the memory controller 100 so that the data is checked for errors and errors in the data are corrected before the data is transmitted to the host 10.

The column decoder 270 decodes a column address YADD and outputs a plurality of selection signals to the Y-gating circuit 230 under the control of the control logic 260.

The page register and S/A block 220 includes a plurality of page buffers respectively connected to a plurality of bit lines. The page buffers may temporarily store data read from the memory cell array 210 during the read operation according to the control of the control logic 260. At this time, each of the page buffers may be implemented using at least two buffers. In the embodiments of the present invention, each page buffer includes two buffers: a first buffer that may be a cache register (e.g., comprising latches 221-11, 221-21, or 221-m1); and a second buffer that may be a data register (e.g., comprising latches 221-1, 221-2, or 221-m). Each of the page buffers may function as an S/A which senses and amplifies a voltage of a bit line connected to each page buffer during the read operation according to the control of the control logic 260.

The Y-gating circuit 230 controls data transmission between the page register and S/A block 220 and the I/O block 280 in response to a plurality of selection signals received from the column decoder 270.

The I/O block 280 may transmit data received from an outside through the I/O pins I/O0 through I/O7 (or a data bus) to the Y-gating circuit 230 and transmit data from the Y-gating circuit 230 to the memory controller 100 through the I/O pins I/O0 through I/O7 (or the data bus). For example, consider a page comprising a 528 Byte code word (e.g., 516 bytes of original data or payload data and 22 bytes attributable to ECC (either as ECC bytes separate from the original data or as a result of an ECC operation on the original data). The Y-gating circuit 230 would operate to output sequentially select portions of the page register and S/A block 220 to output a series of 528 bytes of data via the I/O block 280 (e.g., to ECC circuit 140).

FIG. 6A is a diagram for explaining a read retry operation in the memory system 20 illustrated in FIG. 1.

Referring to FIG. 6A, when a read operation fails, the memory system 20 changes the level of a read voltage and retries a read operation in order to increase the reliability of the non-volatile memory device 200. The read voltage may be the voltage applied to the word line of the physical page storing the data page that is targeted to be read. Other pages in the block containing the target page to be read may have a pass voltage applied to their word lines, sufficient to turn on memory cell transistors operably connected to such word lines (e.g., with gates connected to or part of such word lines). Information about the changed voltage level may be stored in the read retry table 115.

When a program or an erase operation is repeated on the memory cell array 210, a cell distribution may change due to emission of thermal ions, diffusion of charges, ion impurities, program disturbance, high-temperature stress, soft program, over program, and/or the like. In this case, a read operation may fail when the read operation is performed using a predetermined read voltage (\textcircled{1}). Read operation failures may happen more frequently in an MLC than in an SLC because a margin between cell distributions is narrower in the MLC than in the SLC.

In order to restore read errors, the memory controller 100 may perform ECC, by which errors in main data that has been read are corrected, in response to the main data received from the non-volatile memory device 200 and ECC data. When the number of errors occurring in a read operation is beyond the capability of the ECC, the memory controller 100 may control the non-volatile memory device 200 to repeat the read operation.

The non-volatile memory device 200 changes the read voltage and retries the read operation with the newly set read voltage, repeating this pattern until the read operation succeeds (or it is determined the read operation cannot be successful, and the read operation is stopped). FIG. 6A represents a first read operation failing at a read voltage of V1 (\textcircled{1}), followed by a second read operation failing with a read voltage of V2 (\textcircled{2}), followed by a successful read operation with a read voltage at V3 (\textcircled{3}). The read operation may be repeated, increasing a read voltage by a predetermined amount with each read (starting from a predetermined start voltage) until data is accurately read. Alternatively, the read operation may be repeated, decreasing a read voltage by a predetermined amount (starting from a predetermined start voltage) until data is accurately read. The operation of repeating the read operation (e.g., with an altered the read voltage) until the read operation is passed is referred to as a read retry operation. The initial read operation of a page prior to a read retry operation for that page is referred to as a normal read operation. Although the disclosure references a random cache (RC) read operation as a normal read, this is simply one example and any read command may affect a normal read operation. The data read through the read retry operation is transmitted to the host 10 through the memory controller 100.

The nonvolatile memory may be a multi-level cell (MLC) NAND flash memory and the page of data (subject to the initial read and the read retry operation) may be one of two or more pages stored in a physical page of the NAND flash memory. For example, a LSB (least significant bit) page and a MSB (most significant bit) page may be stored in the same memory cells which make up the physical page. Consider a two-bit MLC NAND. To store two-bit data in a two-bit memory cell of a MLC NAND, four ranges of threshold levels are needed. FIG. 6A only shows one threshold distribution range and a read level adjustment of a single read operation parameter, however it is contemplated that multiple parameters may be adjusted in a manner shown in FIG. 6A. To read a page of data from a physical page in a MLC NAND, for some of the data pages, several read operations at different read levels may be needed (each read level may be a voltage between adjacent threshold level ranges—at least initially after programming and prior to any voltage threshold drift due to factors described herein). Thus, rather than a single voltage level being changed by the level set operation, it may be that multiple voltage levels are changed by a level set operation.

FIG. 6B shows four threshold voltage ranges of memory cells, each threshold voltage range representing two bits of data (e.g., 1/1, 1/0, 0/1 and 0/0 shown within the distribution curves which are referred to as MSB/LSB in this example.) In this example, to read the MSB data page from the physical page, a read using a voltage level between the voltage distribution levels 1/0 and 0/1 may be all that is necessary (e.g., at V1a or V2a). If the MSB data page had uncorrectable errors, a read retry changing the voltage from V1a to V2a and reading the MSB data page again at the new read voltage level may be performed, in the manner described herein with respect to FIG. 6A. However, to read the LSB data page (the second bit shown within the distribution curves of FIG. 6B) multiple read levels need to be applied to the word line of the target page—in contrast to the MSB data page read, reading at just one location between the threshold distribution curves would not be sufficient to determine the LSB value and read operations between each of the distribution ranges may be necessary. E.g., for a single read attempt of an LSB data page, three operations may be implemented, each comprising the application of one of three corresponding voltage levels to the word line of the corresponding physical page, the three voltage levels being located between each of the threshold ranges 1/1, 1/0, 0/1 and 0/0 (at least prior to any drift or degradation of Vth levels in the memory cells). Reading MLC data pages in this manner is well known. For further such details, please see the various examples described in U.S. Patent Publication No. 2008/0144370 which is hereby incorporated by reference in its entirety.

FIG. 6B represents a first read attempt of the LSB data page at Vc, V1a and V1b. In this example, it is assumed that the first read attempt of the LSB data page included errors which were uncorrectable by ECC circuit 140 which initiated a read retry. The example of FIG. 6B shows adjusting the voltage levels of two of the read voltages used in the LSB read, changing V1a to V2a and V1b to V2b. Voltage level Vc is left unchanged in this example. Changing some of the voltage levels but not all of the voltage levels may be desirable when it is determined that memory cells programmed to certain voltage threshold ranges are more prone to degradation or shifting than others and/or when a larger Vth gap is provided between adjacent threshold ranges. For example, it may be determined that the memory cells at the erase state of 1/1 do not shift as much as those programmed to the 0/1 state, and thus there is little advantage to change the read level Vc to a new level. While FIG. 6B represents a level set operation changing the level of two of the three voltages for use in the subsequent read retry operation of the LSB data page, all three voltages may be changed with for the single read retry operation. Similarly, only one of the read voltage levels may be changed with the level set operation. Finally, it should be noted that for simplicity of discussion, only an initial normal read operation (at voltages Vc, V1a and V1b) and a single read retry operation (at voltages Vc, V2a and V2b) is shown. But as with FIG. 6A, it is contemplated that multiple read retries may be implemented if needed.

As discussed, a level set operation may affect a set of operation parameters, such as a set of read voltage levels for a subsequent read retry. While certain embodiments described herein may reference changing a single voltage level, this is for the ease of description. All embodiments described herein contemplate modifications where in addition to a single operation parameter (e.g., voltage level) being modified in a read retry operation (or in a level set operation), multiple operation parameters (e.g., voltage levels) may be changed by a level set operation. The operation for these alternative embodiments may include applying a first set of read reference voltages (e.g., in sequence to distinguish between neighboring threshold ranges used to identify multiple bits of data in an MLC non volatile memory cell) to a word line of the first physical page during the first reading (which may be a normal read or a read retry read) to determine memory cell data for each of multiple memory cells of the first physical page, and applying a second, different, set of read reference voltages to the word line of the first physical page during the second reading (e.g., a read retry read) to determine memory cell data for each of multiple memory cells of the first physical page.

The number of repetitions of reading performed until the read operation is determined to be unsuccessful may be increased according to the change in cell distribution. The read retry table 115 may store a change in the read level whenever a read count (e.g., an index “i”) increases (this change may be stored as a difference between read voltages, a percentage or the full read voltage for each retry may be stored). The read count may be predetermined.

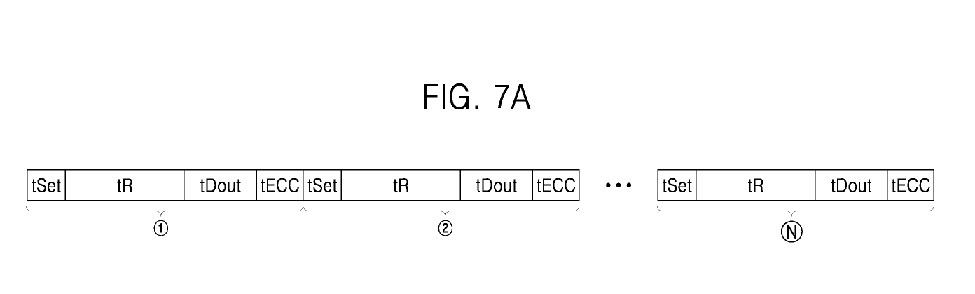

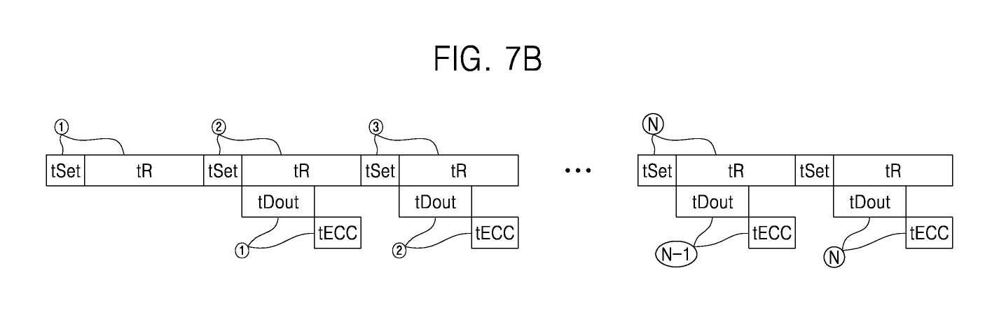

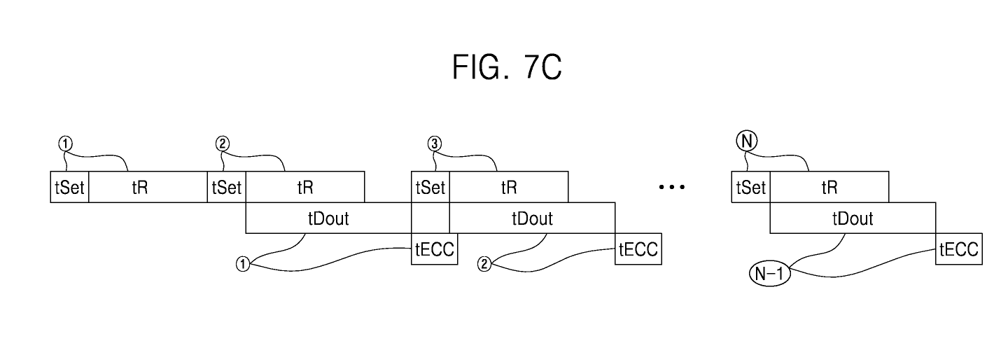

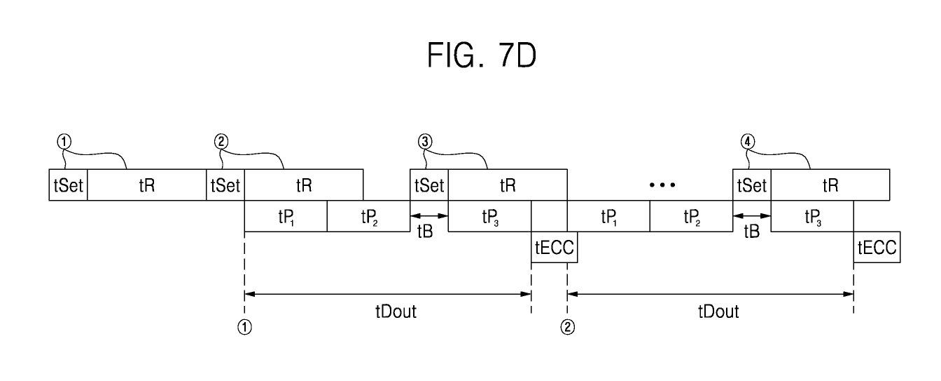

FIG. 7A is a timing diagram showing a sequence of the read retry operation as a comparative example. FIGS. 7B through 7D are timing diagrams showing sequences of read retry operations according to exemplary embodiments. In FIGS. 7B through 7D, a normal read operation to a target page may already have occurred (but not shown) (which may be, e.g., immediately prior to the read retry operations to the target page depicted in FIGS. 7A through 7D). In other embodiments, the normal read operation such target page may be ongoing at the start of the first read retry operation of FIGS. 7B through 7D.

Referring to FIG. 7A, the duration of the read operation includes a target read level set time tSet, a read time tR, a read data out time tDout, and an ECC correction time tECC. The target read level set time tSet may be the amount of time taken to change and set a read level. For example, operations during this time tSet may be include accessing the read retry table 115 to determine a new read level, sending a command from the memory controller 100 to the non-volatile memory device 200 with the new read level, and an internal setting of the non-volatile memory device 200 to be ready to initiate a read at the new read level in response to the command to read at the new read level. As another example, the time tSet may be an amount of time for the non-volatile memory to access a register or a table internal to the non-volatile memory to determine a new read level, and internally setting the word line voltage generator for the target page to the new read level. The read time tR may be the amount of time taken to read data from a memory cell array and store the data in a cache register. For example, this time tR may include sending a read command from the memory controller 100 to the non-volatile memory device 200 and performing a reading operation internal to the non-volatile memory device 200 to transfer a page of data (such as a code word) from a physical page of the non-volatile memory 200 to the page register and S/A 220. Alternatively, the time tR may not include sending a read command from the memory controller 100 to the non-volatile memory; all embodiments disclosed herein contemplate an alternative where a new read command is unnecessary and the non-volatile memory references an address received from a previous read command to determine the target page (exemplary details of this alternative are found elsewhere in this disclosure). In this alternative embodiment, the read retry operation may be initiated by the level set command received by the memory controller (which may be a read command with level setting information in this instance) or, if the read level information is obtained from a source internal to the non-volatile memory, the read retry operation may be initiated automatically (e.g., after the previous read retry operation has finished) or may be initiated with a signal from the memory controller (e.g., a toggle signal or command on one or more of the I/O lines). The read data out time tDout may be the amount of time taken to output the data in a data register (e.g., the page register and S/A 220) to a source external to the non-volatile memory 200 (e.g., memory controller 100). The ECC correction time tECC may be the time it takes for an error correction circuit 140 to analyze the received page of data (e.g., a code word) to determine if an error exists in the page of data. In some examples, tECC may also include time to determine if the errors are (or error is) correctable, and it may also include correcting the error(s) if the error(s) are correctable.

In the comparative example illustrated in FIG. 7A, when a read retry is performed N times, a total read retry duration is the sum of the target read level set time tSet, the read time tR, the read data out time tDout, and the ECC correction time tECC multiplied by the number N of read retries.

However, when at least certain portions of consecutive read retries are performed concurrently, the total read retry duration is reduced. As shown in the example of FIG. 7B, the operation of outputting first data read in a first read operation (e.g., to memory controller 100) and performing the ECC on this first data (e.g., by ECC circuit 140) is performed in parallel with an operation of reading second data in a the following second read operation. Thus, the total time of two back to back read retry operations is reduced by the sum read data out time tDout and the ECC correction time tECC of the first read operation. As will be noted, similar time savings is gained for each read retry due to the parallel operations of sequential read retry operations.

In detail, in the timing diagram illustrated in FIG. 7B, in a first read retry (\textcircled{1}) a first read voltage is set during the target read level set time tSet and first retry data is read and temporarily stored in the first register, e.g., the cache register 221-11 in the page register and S/A block 220 during the read time tR. In this example, since no previous data is in the second register, i.e., the data register 221-1, data output does not occur in the memory cell array 210 during the read time tR.

In a second read retry (\textcircled{2}) the read level is set to a second read voltage from the first read voltage during the target read level set time tSet. First read retry data is moved from the first buffer (e.g., cache register 221-11 to 221-m1) to the second buffer (e.g., data register 221-1 to 221-m). Second retry data is read and temporarily stored in the first buffer in the page register and S/A block 220 during the read time tR. At this time, while the first buffer reads the second retry data from a physical page of the memory cell array 210 and temporarily stores it during the read time tR, the second buffer outputs the first retry data previously stored therein to the memory controller 100 (read data out time tDout) and the memory controller 100 corrects errors in the first retry data (ECC correction time tECC). Even though it the memory controller 100 (the ECC circuit 140) has not determined that the number of errors in the first retry data is beyond the capability of the ECC circuit 140, the memory controller 100 may command the non-volatile memory device 200 to repeat the read operation with different read levels (e.g., the memory controller 100 may issue a read retry command to non-volatile memory device 200 prior to determining whether or not errors of the first retry data are correctable via ECC operations. In the example of FIG. 7B, the subsequent read retry (second read retry) is initiated with the second target read level set at time tSet prior to the first retry data being sent from the nonvolatile memory 200 to memory controller 100 and ECC operations by ECC circuit 140.

When the read operation is repeated, in an N-th read retry (\textcircled{N}) an N-th read voltage is set during the target read level set time tSet and N-th retry data is read and stored in the first buffer (221-11 to 221-m1) in the page register and S/A block 220 during the read time tR. At this time, while the first buffer 221-11 reads the N-th retry data from the memory cell array 210 and temporarily stores it during the read time tR, the second buffer (221-1 to 221-m) outputs (N−1)-th retry data previously stored therein to the memory controller 100 (read data out time tDout) and the memory controller 100 corrects errors in the (N−1)-th retry data (ECC correction time tECC). When the number of errors in the (N−1)-th retry data is within the capability of the ECC, the memory controller 100 may terminate the read operation of the non-volatile memory device 200 and transmits the (N−1)-th retry data to the host 10. Alternatively, when the number of errors in the (N−1)-th retry data is within the capability of the ECC, the memory controller 100 may simply ignore subsequent operations of nonvolatile memory 200 associated with the N-th read retry (e.g., fail to input N-th read retry data).

Consequently, while data is internally read in the non-volatile memory device 200 (e.g., from a physical page of the memory cell array 210 to the first buffer) during the read time tR in a current read operation, data previously read is output (tDout) from the non-volatile memory device 200 to the memory controller 100 and then subjected to ECC (tECC) by the memory controller 100, so that a total read retry duration (over multiple read retries) can be reduced. When the total read retry duration is reduced, the read speed of the non-volatile memory device 200 may be increased, thereby increasing the performance of the memory system 20. Further, additional read retry operations may be performed within the same or less time to increase reliability.

It is illustrated in FIG. 7B that the sum of the read data out time tDout and the ECC correction time tECC is similar to the read time tR, but the present invention is not restricted thereto.

The read data out time tDout may be longer than the read time tR, as illustrated in FIG. 7C, or vice versa. When the read data out time tDout is longer than the read time tR, the read data out time tDout may not be continuous but may be interrupted, such as with a target read level set operation (time tSet), so that the read data out time tDout may be discontinuous, as illustrated in FIG. 7D. For example, the read data out time tDout may be divided into at least two parts of data out time tP (three parts of data out time tP₁, tP₂, and tP₃ for each read operation (e.g., page read) are shown in FIG. 7D). The part of data out time tP may be the amount of time taken to output a part of the data in a data register of the non-volatile memory to a location external to the non-volatile memory (e.g., to the memory controller 100). Each part may be half, or a quarter of the total page, e.g., or may be variable for each read operation. The target read level set operation (during time tSet) may be inserted during time tB between two parts of data out time tP (here, between first and second parts of a data output tP₁, tP₂, and a third part of the data output tP₃).

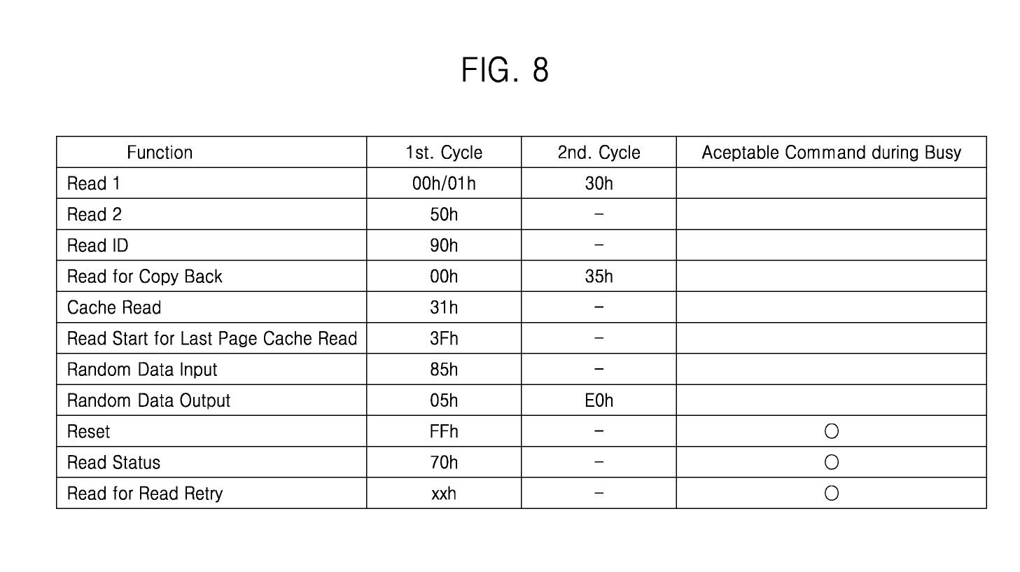

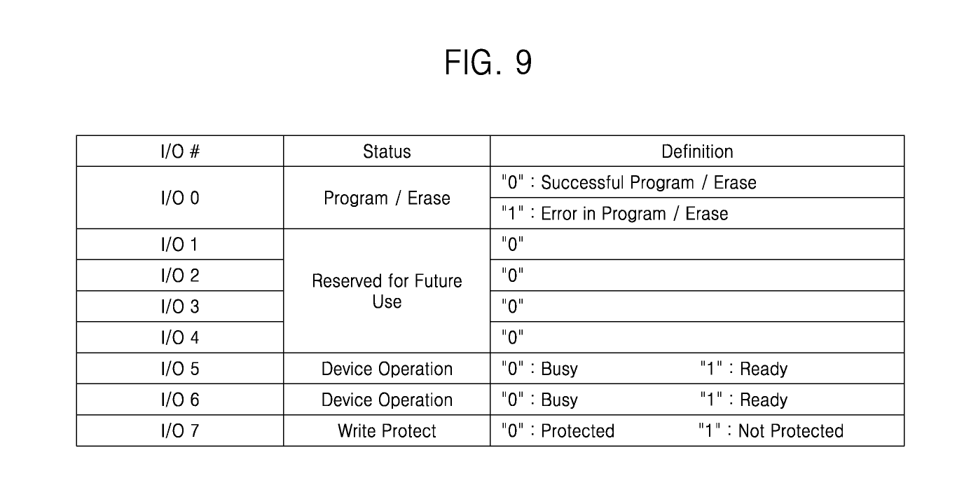

FIG. 8 is a diagram showing example command codes sent by the memory controller 100 to the non-volatile memory device 200 illustrated in FIG. 1 according to some embodiments. FIG. 9 is a diagram showing status signals output from the non-volatile memory device 200 to the memory controller 100 illustrated in FIG. 1 according to some embodiments.

Referring to FIG. 8, the memory controller 100 outputs a command for controlling the operation of the non-volatile memory device 200 through I/O pins I/O0 to I/O7. The command may be sent with an address of data in the non-volatile memory device 200 according to an operation to be controlled. This address may be sent over multiple cycles inserted between the first cycle and second cycle of the command. For example, the entire output may comprise 00h, add0h, add1h, add2h, add3h, add4h and 30h where 00h and 30h comprise the command first cycle and second cycle respectively, and add0h, add1h, add2h, add3h and add4h comprise the address (e.g., each of the sequentially sent parts of the total address add0h, add1h, add2h, add3h and add4h comprise an 8 bit part of the total address, each 8 bit part being sent in parallel). For instance, in a read operation, the memory controller 100 may send in sequential order a command 00h, an address of data to be read, and a command 30h to the non-volatile memory device 200. Accordingly, the non-volatile memory device 200 reads data of a page selected by the address from the memory cell array 210 using the page register and S/A block 220 and outputs the data to the memory controller 100. At this time, the memory controller 100 may send a command 70h to the non-volatile memory device 200 to check the read status of the non-volatile memory device 200. The non-volatile memory device 200 may send a ready or busy signal through one or more I/O pins (e.g., I/O5 and I/O6) to the memory controller 100 in response to the command 70h. The memory controller 100 detects whether the read operation has been completed based on the ready or busy signal.

In some embodiments, a ‘read for read retry’ command may be used to initiate a read retry. The ‘read for read retry’ command may be a newly defined command or one of conventional read commands—for example, a ‘random cache (RC) read’ command. For example, if the ‘read for read retry’ command is a new command, it may simply consist of a first cycle command code (e.g., 8 bits) unique from other command codes (the code xxh may be assigned during the design phase of the non-volatile memory)—no address information need be submitted with the new ‘read for read retry’ command in this example. The non-volatile memory 200 recognizes this unique ‘read for read retry’ command upon input to a command decoder of the non-volatile memory as the ‘read for read retry’ command and initiates a read retry to a previously read page. The page to be read with the read for read retry operation may be identified by the address of the most recently read page or the second (or third, fourth, etc.) most recently read page (e.g., the page associated with the address received with the last read command or second to last read command). Using a new command in this fashion would allow for a quick command cycle without necessitating resending address information to the non-volatile memory 200 from the memory controller 100.

Whether or not the page to be read with the unique read for read retry command is the most recently read page or an earlier read page may depend on a timing of the ECC operation as compared to the pipelined ECC/reading of the non-volatile memory. If the ECC operation detects an uncorrectable error in a read page of data prior to issuing a new normal read command to the non-volatile memory 200, the non-volatile memory 200 may perform a read for read retry command for the most recently read page. However, if the ECC operation detects an uncorrectable error in a read page of data after issuing one or more new normal read commands, the read retry command should be performed for that read page. For example, assume a read command is issued for a first page. If n (n being an integer) read commands are issued to the non-volatile memory after issuing the read command for the first page but prior to detecting an uncorrectable error of the read first page, then the page to be subjected to the read for read retry operation may be that identified by an address received with the previous n+1 read command (i.e., the address of the first page). For example, if one normal read command has been issued to the non-volatile memory prior to detecting an uncorrectable error of a read page, the read for read retry command should be performed for the second to last read command received by the non-volatile memory. Which address to be used may be predetermined based on the known pipeline timing of the ECC/reading operations (which may set in the design stage).

Alternatively, the memory controller 100 may send a ‘read for read retry’ command in a currently known command format, such as a random cache read command (where the page address to be read is resent with the read command such as in the manner described above). The RC read is an operation in which when ECC fails (e.g., in a cache read operation), a read command with an address of a page (hereinafter, referred to as a target page) storing data of which reading has failed are sent to the non-volatile memory device 200 and the non-volatile memory device 200 performs a read retry on the target page (which may be only on the target page without reading other pages in response to the read command). Many embodiments disclosed herein describe the use the random cache (RC) read command as the read for read retry command, but the present invention is not restricted there-to and all of these embodiments contemplate use of other commands (whether other normal read commands or the unique read for read retry command).

FIG. 9 shows the signals of I/O pins I/O0 through I/O7 sent by the non-volatile memory device 200 to the memory controller 100 when the memory controller 100 sends a command to the non-volatile memory device 200 to check the status of the non-volatile memory device 200. The eight I/O pins I/O0 through I/O7 are also the pins through which data is input to or output from the non-volatile memory device 200. One or more of the I/O pins I/O0 through I/O7 outputs a signal informing the memory controller 100 of the status of the non-volatile memory device 200. For instance, the I/O pin I/O0 outputs a signal indicating the status regarding a program operation or an erase operation. When the program or erase operation has been successful, the I/O pin I/O0 outputs a low signal of “0”; otherwise, it outputs a high signal of “1”.

The I/O pin I/O5 outputs an array R/B signal indicating whether the memory cell array 210 is busy with an operation (e.g., a program operation or a read operation) during a cache operation. For instance, the array R/B signal may indicate whether the non-volatile memory device 200 is sending data temporarily stored in the cache register 221-m1 to the data register 221-m and/or is temporarily storing data read from a target page of the memory cell array 210 in the cache register 221-m1. When the non-volatile memory device 200 is performing an operation, the array R/B signal is output at logic low “0” to indicate the memory cell array 210 is busy. Here, the assertion of a logic low “0” on pin I/O5 by the non-volatile memory device 200 may be a flag for and detected by the memory controller 100, but instead, this flag may be a logic high “1” assertion by the non-volatile memory device. When the non-volatile memory device 200 is not performing this operation but is standing by, the array R/B signal is output at logic high “1”. When the memory cell array 210 is busy, it may not be possible for certain non-volatile memory devices to adjust read voltages (e.g., with a level set command). Thus, the array R/B signal on I/O pin may be used to inform the controller not to send a level set command. It may be possible, however, that other command may be received by the non-volatile memory device 200 at this time, such as a new read command, a read for read retry command, an erase command and/or a write or program command.

The I/O pin I/O6 outputs a host R/B signal. The host R/B signal may indicate the operation status (e.g., a program, erase and/or read operation) of the non-volatile memory device 200. Alternatively, or in addition, the host R/B signal may indicate whether the non-volatile memory device 200 can accept further commands, such as whether the host 10 or memory controller 100 is able to send a new command (e.g., new read, write or erase command) to the non-volatile memory device 200. In the current embodiments of the present invention, the host R/B signal may indicate whether the data register 221-m has data read from a target page to the memory controller 100 through the I/O block 280 that is to be output (e.g., to the memory controller 100). When the non-volatile memory device 200 cannot accept a new command, the host R/B signal is output at logic low “0”. When the non-volatile memory device 200 can accept a new command (e.g., the memory device 200 is standing by), the host R/B signal is output at a high level of “1”. Here, the assertion of a logic low “0” on pin I/O6 by the non-volatile memory device 200 may be a flag for and detected by the memory controller 100, but instead, this flag may be a logic high “1” assertion by the non-volatile memory device. The host R/B signal may be output through a special pin (e.g., a host R/B pin) instead of the I/O pin I/O6. The array R/B signal may also be output through a special pin instead of the I/O pin I/O5. The host R/B signal and the array R/B signal may also be output through one pin (e.g., one among I/O pins or a special pin).

Consequently, the array R/B signal (e.g., on I/O5) may be a status signal indicating whether an internal operation of the non-volatile memory device 200 has been completed and the host R/B signal (e.g., on I/O6) may be a status signal indicating whether the non-volatile memory device 200 is able to be accessed by an external device (e.g., the host 10 or the memory controller 100).

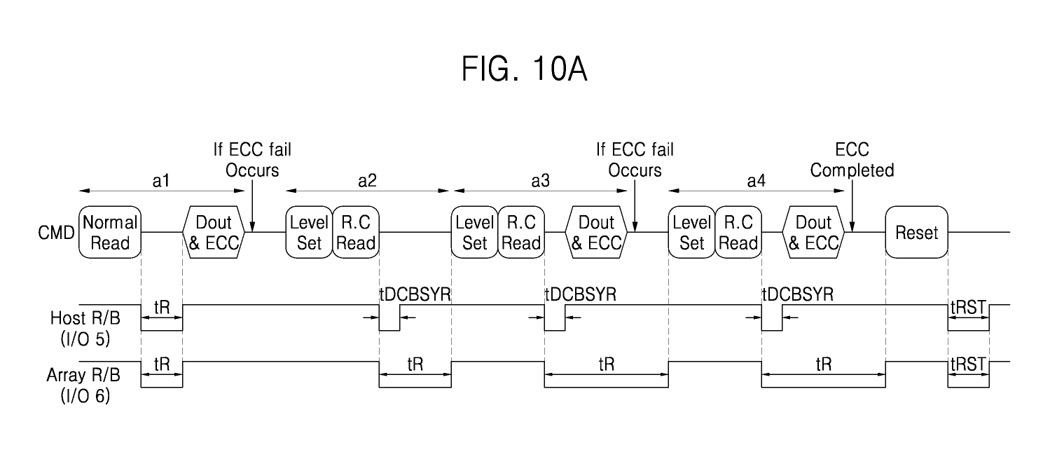

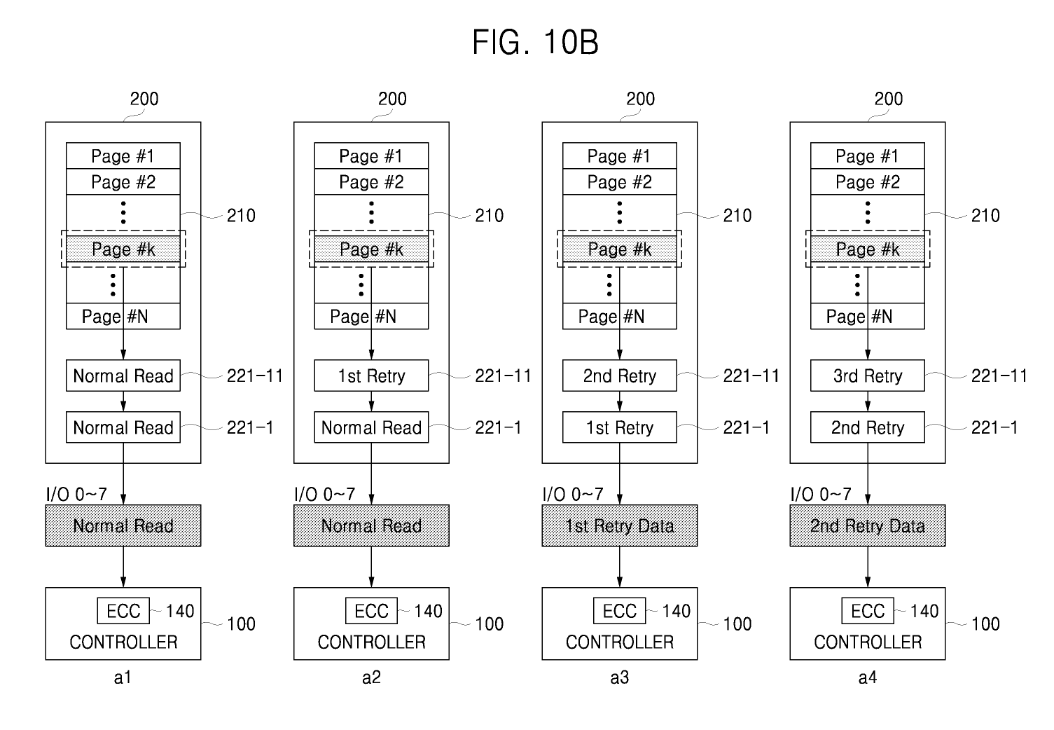

FIG. 10A is a timing chart of the operation of the memory system 20 illustrated in FIG. 1 according to some embodiments of the present invention. FIG. 10B is a diagram showing the operation of the memory system 20 according to the embodiments illustrated in FIG. 10A.

FIG. 10A shows a command signal CMD transmitted from the memory controller 100 to the non-volatile memory device 200, a host R/B signal, and an array R/B signal indicating the internal operation status of the non-volatile memory device 200.

Referring to FIGS. 8 through 10B, the memory controller 100 sends a normal read command, e.g., a read command expressed by 00h or 01h, to the non-volatile memory device 200 through data pins I/Ox (“x” is a natural number) at the request of the host 10. At this time, duration of the normal read operation is denoted by “a1”.

Before performing the read operation, the memory controller 100 may send a command 70h, i.e., a read status command to the non-volatile memory device 200 to check host R/B and array R/B. In other words, the memory controller 100 checks whether the non-volatile memory device 200 is ready for the read operation (i.e., is in a read ready status) or is busy doing the read operation (i.e., is in a read busy status) using the read status command.

In response to the command 70h, the non-volatile memory device 200 may data indicating the status of the non-volatile memory device 200 through one or more of the I/O pins I/O0 through I/O7. At this time, the I/O pin I/O5 may output the host R/B signal and the I/O pin I/O6 may output the array R/B signal.

For instance, as illustrated in FIG. 10A, at certain times the array R/B signal (I/O6) is “0” even though the host R/B signal (I/O5) has transitioned “0” to “1”, indicating the non-volatile memory device 200 is busy performing a current operation but may accept, but not necessarily immediately act upon, certain command. For example, the non-volatile memory 200 might accept a new read command but perform the new read command until the array R/B signal transits from “0” to “1”. However, the non-volatile memory 200 might not be able to accept a level set command until the array R/B signal (I/O5) transitions from low to high.

Assume a sequence of normal read commands where each read page of data is subsequently subjected to an ECC operation. Each ECC operation may include analysis to detect errors in a read data page, determining if detected errors are correctable, correcting errors if the errors are correctable and/or signaling that a read page contains uncorrectable errors. Read retries may be implemented in certain sequences, as shown by the timing diagram of FIG. 10A and the block diagram of FIG. 10B. During time a1, a normal read command is issued from memory controller 100 to non-volatile 200 to read a target page (here, Page#k. When the non-volatile memory device 200 receives the normal read command, a target page Page#k is read and read data of the target page Page#k is output to the memory controller 100 through the page register and S/A block 220 and the ECC circuit 140 performs ECC on the read data of the target page Page#k. Specifically, read Page#k data read from memory cell array 210 is temporarily stored in the cache register 221-11 and transferred to the data register 221-1, and then transferred from the non-volatile memory 200 to the memory controller 100 where the ECC circuit performs ECC on the read data. At this time, the host R/B signal and the array R/B signal are both output at logic low “0”, which indicates that the read operation is being performed, during the read time tR.

When the host R/B signal and the array R/B signal transit from “0” to “1”, normal read data in the data register 221-1 is output and the ECC circuit 140 performs ECC on the read Page#k data. When errors in the read Page#k data are not correctable by the ECC, (e.g., if ECC fail occurs), the memory controller 100 commands the non-volatile memory device 200 to perform a read retry.

During a second read operation during time a2, the memory controller 100 may set a new read level before the read retry. At this time, the read level may be reset by increasing or decreasing a current read level by or to a predetermined value using the read retry table 115. The number of resets of a read level, i.e., the number of read retry attempts to be performed on a particular page prior to determining the read operation is a failure also may be predetermined in the read retry table 115 to limit the number of read retries. In addition, a value stored in the read retry table 115 may represent a new read level or represent an increment or a decrement from an old read level (e.g., a voltage increment/decrement or a percentage increment/decrement).

After the level set operation during time a2, the non-volatile memory device 200 receives an RC read command (random cache read command) from the memory controller 100 with the address for Page#k. The non-volatile memory device 200 performs a second read operation on Page#k in response to the RC read command.

The non-volatile memory device 200 reads data (i.e., first retry data) from the target page Page#k, and temporarily stores the first retry data in the cache register 221-11.

In order to perform a read retry on the target page Page#1 in the non-volatile memory device 200, the host R/B signal needs to transit from “1” to “0”. However, even while the non-volatile memory device 200 is actually performing the read retry on the cache register 221-11 during the read time tR, the host R/B signal may transits from “0” to “1” (tDCBSYR) only after the end of the operation of the data register 221-1 is confirmed. In other words, even when the host R/B transits to “1”, the non-volatile memory device 200 may be actually performing the read retry (reading data from Page#k). Accordingly, the memory controller 100 monitors the array R/B signal to detect a time point at which the read retry is completed and starts a third read operation (i.e., a second read retry at time a3) when the array R/B signal transits from “0” to “1”. This second read retry at time a3 may be performed prior to the completion or even prior to the initiation of an ECC operation on the first read retry read data (i.e., read data resulting from the first read retry operation at time a2). As will be apparent, in this example, the second read retry command is sent and the second read retry operation is initiated on Page#k (at time a3) even before the first read retry read data is transmitted to memory controller 100.

Meanwhile, at time a2, since the normal read data (from the normal read operation of Page#k during time a1) in the data register 221-1 has already failed in the ECC, any data output from the non-volatile memory 200 to memory controller and/or any ECC operation on this data may be ignored during time a2, i.e., or these operations may not be performed during time a2.

During the time a3, the memory controller 100 sets the read level to a new value before the second read retry. At this time, a new read level may be set using the read retry table 115 in a manner as described above.

Also during time a3, after the new read level is set, the non-volatile memory device 200 receives an RC read command with an address identifying Page#k from the memory controller 100. The non-volatile memory device 200 performs a third read operation of Page#k (the second read retry operation of Page#k) in response to the RC read command.

The non-volatile memory device 200 transmits second read data, i.e., the first retry data that has temporarily stored in the cache register 221-11 to the data register 221-1, reads data (i.e., second retry data) from the target page Page#k, and temporarily stores the second retry data in the cache register 221-11.

During the third read operation at time a3, data is read from Page#k again and stored in the cache register 221-11 (second retry data of Page#k), the data register 221-1 outputs the first retry data (i.e., the second read data of Page#k) to the memory controller 100 during the read data out time tDout and the memory controller 100 performs ECC on the first retry data during the ECC correction time tECC of time a3. The memory controller 100 determines whether to perform a third read retry (i.e., a fourth read operation on Page#k) according to a result of the ECC operation on the first retry data.

In order to allow a read retry on the target page Page#1 in the non-volatile memory device 200 during the third read operation, the host R/B signal (I/O5) transitions from “1” to “0”. Even while the non-volatile memory device 200 is actually performing the read retry on the cache register 221-11 during the read time tR, the host R/B signal may transition from “0” to “1” (tDCBSYR).

Accordingly, the memory controller 100 monitors the array R/B signal (I/O6) to detect a time point at which the read retry is completed. The array R/B signal transitions from “0” to “1” when the second retry data has been read from Page#k to cache register 221-11 and the first retry data has been transferred from the cache register 221-11 and the data register 221-1. At this time, the memory controller 100 receives the first retry data and performs ECC on the first retry data using the ECC circuit 140. If an ECC fail occurs as a result of this ECC operation (e.g., the first read retry data is determined to have uncorrectable errors), the memory controller 100 commands the non-volatile memory device 200 to perform a third read retry (i.e., a fourth read operation) on Page#k at time a4. For the purposes of this explanation, it is assumed an ECC fail does occur in performing an ECC operation on the first read retry data and thus a third read retry is performed.

During the fourth read operation during time a4, the memory controller 100 sets the read level to a new value before the third read retry. At this time, a new read level may be set using the read retry table 115.

Also during time a4, after the new read level is set, the non-volatile memory device 200 receives an RC read command with the address of Page#k from the memory controller 100. The non-volatile memory device 200 performs the third read retry (the fourth read operation) on Page#k in response to the RC read command.

During time a4, the non-volatile memory device 200 transmits the second retry data of Page#k (the third read data of Page #k) temporarily stored in the cache register 221-11 to the data register 221-1, outputs the second retry data from data register 221-1 to memory controller 100, reads data (i.e., third retry data) from the target page Page#k, and temporarily stores the third retry data in the cache register 221-11.

While the third read retry operation on Page#k at time a4 is being performed and the associated read data is stored in the cache register 221-11 during the read time tR, the data register 221-1 outputs the second retry data to the memory controller 100 during the read data out time tDout and the memory controller 100 performs ECC on the second retry data during the ECC correction time tECC. The memory controller 100 determines whether to initiate a fifth read operation on Page#k, i.e., a fourth read retry, according to a result of the ECC.

In order to allow a read retry on the target page Page#k in the non-volatile memory device 200 during the third read retry operation, the host R/B signal (e.g., I/O5) transitions from “1” to “0”. While the non-volatile memory device 200 is performing the read retry during the read time tR, the host R/B signal may transition from “0” to “1” (tDCBSYR) and thereby allow acceptance of certain new commands (e.g., such as a new read command, a new read retry command, an erase command and/or a write or program command).

The memory controller 100 checks the array R/B signal (e.g., I/O6). When the array R/B signal transitions from “0” to “1” and the ECC of the third read data, i.e., the second retry data is successful (that is, ECC is completed), the memory controller 100 outputs a reset command (FFh in FIG. 8) to refresh the non-volatile memory device 200.

The non-volatile memory device 200 and the host 10 are reset in response to the reset command and a read retry operation cycle ends. Resetting the non-volatile memory device 200 may include resetting the read level voltage (such as to a predetermined value associated with normal read operations). Also at this time, a table may be updated, either in the RAM 110 of the memory controller, in the non-volatile memory (such as in a meta-data field of Page#k or a separate non-data section of the non-volatile memory (e.g., and file translation layer (FTL) section)) or both. The updated table may reflect the fact that a read retry was necessary on Page#k to have Page#k rewritten to a new page within the non-volatile memory with voltage threshold distribution levels being reset to their normal ranges (refer to FIG. 6A and related discussion).

It is noted with respect to the embodiment described above, successive normal read operations were not pipelined but rather each normal read operation had read data read to cache register 221-11, transferred to data register 221-1, transferred from the non-volatile memory 200 to the memory controller 100 and an ECC operation performed on the read data prior to issuance of a subsequent normal read command. However, it is contemplated that in an alternative embodiment, the Page#k+1 data may be normally read from the memory cell array 210 and stored in the cache register 221-11 while previously normally read data (e.g., Page#k normal read data) is stored in data register 221-1, is transferred to the memory controller 100 and an ECC operation is performed on such Page#k normal read data. For example, in an alternative embodiment, during time a1, in FIGS. 10A and 10B, the normal read command may be associated with a command to read Page#k+1 while the Dout & ECC operations may be associated with outputting Page#k read data from the non-volatile memory 200 to the memory controller 100 and performing ECC operations on Page#k read data. In time a2, in FIGS. 10A and 10B, the Dout & ECC operation shown may be associated with Page#k+1 (these result of these Dout & ECC operations may either be stored when read retries are performed in a manner described above, or the Page#k+1 data may be discarded and a new normal read command for Page#k+1 may be issued after the read retry cycle for Page#k is completed in a manner as described above).

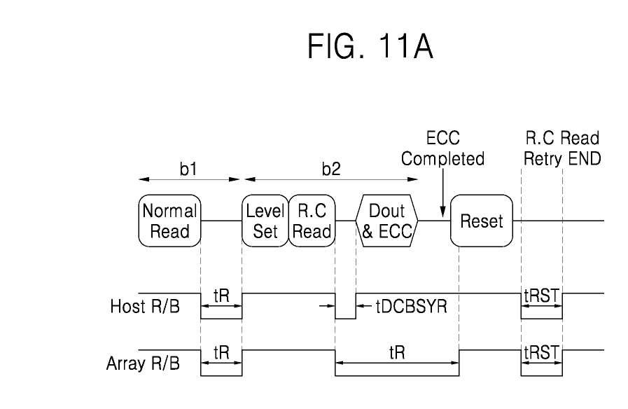

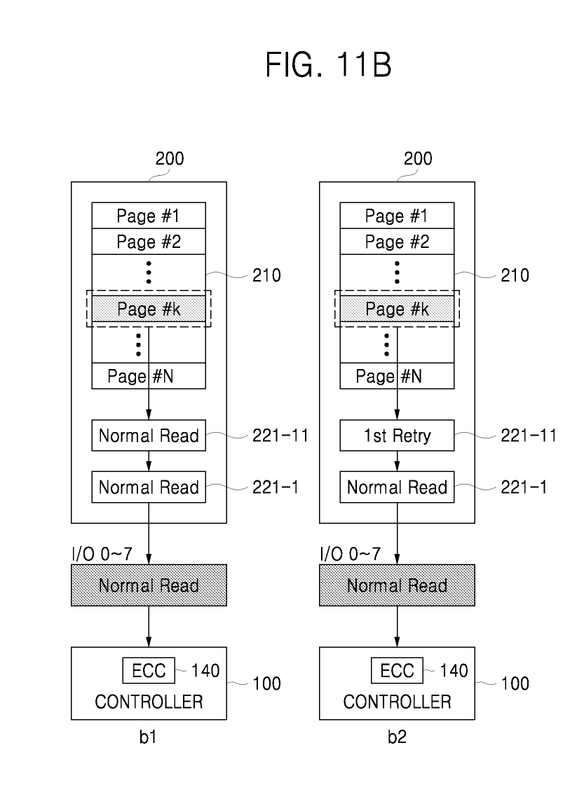

FIG. 11A is a timing chart of the operation of the memory system 20 illustrated in FIG. 1 according to other embodiments of the present invention. FIG. 11B is a diagram showing the operation of the memory system 20 according to the embodiments illustrated in FIG. 11A. The description of the embodiments illustrated in FIGS. 11A and 11B will focus on differences from the embodiments illustrated in FIGS. 10A and 10B.

In response to a normal read command, the non-volatile memory device 200 reads a target page Page#k and temporarily stores normal read data of the target page Page#k in the cache register 221-11. At this time, a host R/B signal and an array R/B signal are both output at logic low “0”, which indicates that a read operation is being performed. First read data, i.e., the normal read data temporarily stored in the cache register 221-11 is transmitted to the data register 221-1.

When the host R/B signal and the array R/B signal transit from “0” to “1”, the memory controller 100 performs a read retry operation.

In other words, the embodiments illustrated in FIGS. 11A and 11B are different from those illustrated in FIGS. 10A and 10B in that the non-volatile memory device 200 is controlled to perform a read retry operation on Page#k even though the normal read data of Page#k has not been output to the memory controller 100 (and similarly, no ECC operation has been performed on Page#k).

During a second read operation b2, the memory controller 100 sets the read level to a new value. When a read level is set, the non-volatile memory device 200 receives an RC read command (random cache read command) from the memory controller 100 with the address of Page#k. The non-volatile memory device 200 performs a first read retry (the second read operation) on Page#k in response to the RC read command. While the second read operation, i.e., a first read retry is being performed on the cache register 221-11 during the read time (tR), the data register 221-1 outputs the normal read data, i.e., the first read data of Page#k to the memory controller 100 during the read data out time tDout and the memory controller 100 performs ECC on the normal read data during the ECC correction time tECC. The memory controller 100 determines whether to perform a third read operation, i.e., a second read retry according to a result of the ECC.

When the ECC is successful, i.e., completed, the memory controller 100 sends a reset command to the non-volatile memory device 200 to terminate the read retry operation that has been started unconditionally.

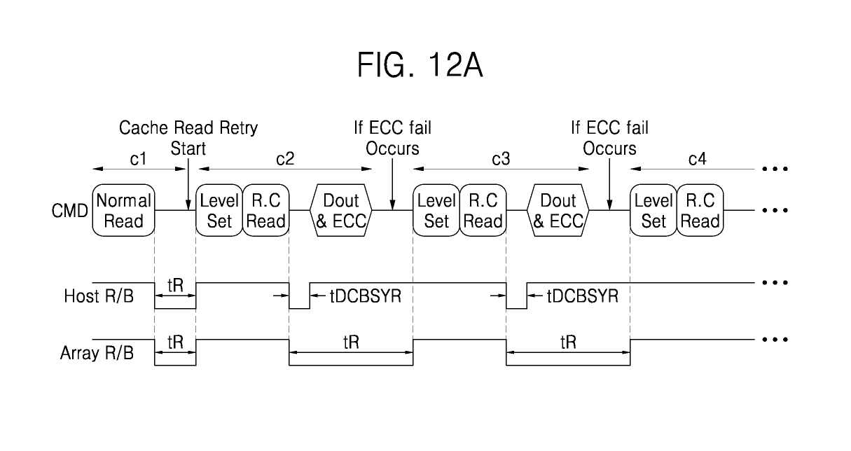

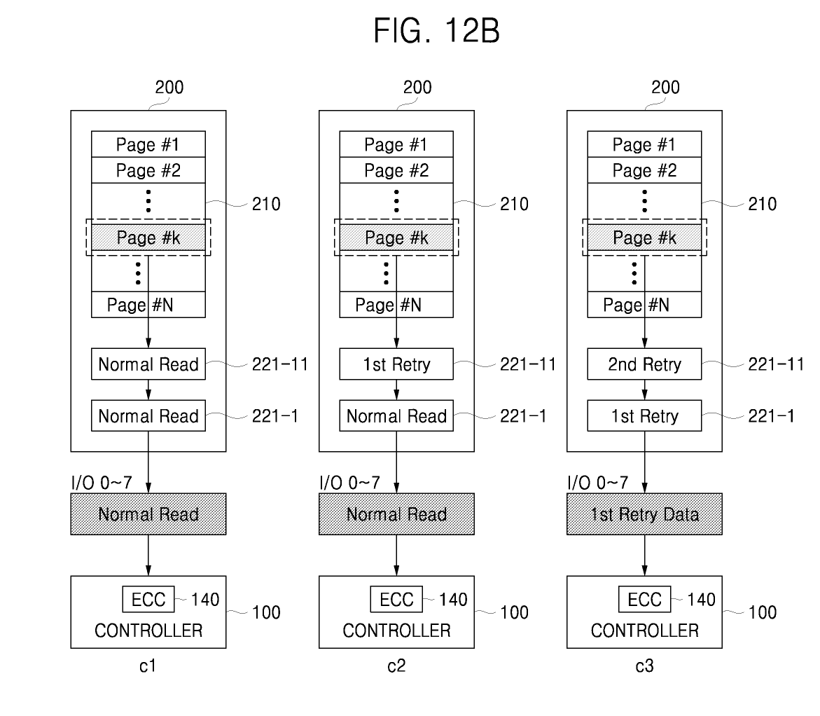

FIG. 12A is a timing chart of the operation of the memory system 20 illustrated in FIG. 1 according to further embodiments of the present invention. FIG. 12B is a diagram showing the operation of the memory system 20 according to the embodiments illustrated in FIG. 12A. The description of the embodiments illustrated in FIGS. 12A and 12B will focus on differences from the embodiments illustrated in FIGS. 10A and 10B.

During time c1, a normal read command is sent with the address of Page#k from the memory controller 100 to the non-volatile memory 200. In response to a normal read command, the non-volatile memory device 200 reads a target page Page#k and temporarily stores normal read data of the target page Page#k in the cache register 221-11. At this time, a host R/B signal and an array R/B signal are both output at logic low “0”, which, in this operation, indicates that a read operation is being performed within the non-volatile memory (e.g., a read access of memory cell array 210). First read data, i.e., the normal read data temporarily stored in the cache register 221-11 is transmitted to the data register 221-1.

Similarly to the embodiments illustrated in FIG. 11A, when the host R/B signal and the array R/B signal transitions from “0” to “1”, the memory controller 100 commands the non-volatile memory device 200 to perform a read retry operation (at time c2, a level set operation is followed by a subsequent read command for Page#k).

While the non-volatile memory device 200 is performing a second read operation during time c2, the memory controller 100 outputs and performs ECC on the first read data, i.e., the normal read data read in response to the normal read command at time c1. When the ECC fails, the memory controller 100 controls the non-volatile memory device 200 to perform a third read operation (i.e., a second read retry).

The embodiments illustrated in FIGS. 12A and 12B are different from those illustrated in FIGS. 10A and 10B in that the non-volatile memory device 200 is controlled to perform a read retry operation prior to the transmission of the normal read data to the memory controller 100 (and prior to an ECC operation on the normally read data). A RC read retry is repeated if ECC fails during the read retry operation.

Before a third read operation c3, the memory controller 100 resets the read level. The non-volatile memory device 200 repeats a read retry until ECC of data transmitted to the memory controller 100 is completed successfully or until a sufficient number of read retries have been performed (e.g., a predetermined number of read retries have been performed).

According to the above embodiments, certain operations of a current read retry occur during the output of and/or during an ECC operation on data associated with a previous read retry operation, so that the duration of a total read retry cycle is reduced. When the duration of a total read retry cycle is reduced, the read speed can be increased and/or additional read retries may be performed to increase the reliability of the non-volatile memory. As a result, the performance of the memory system 20 including the non-volatile memory device 200 is increased.

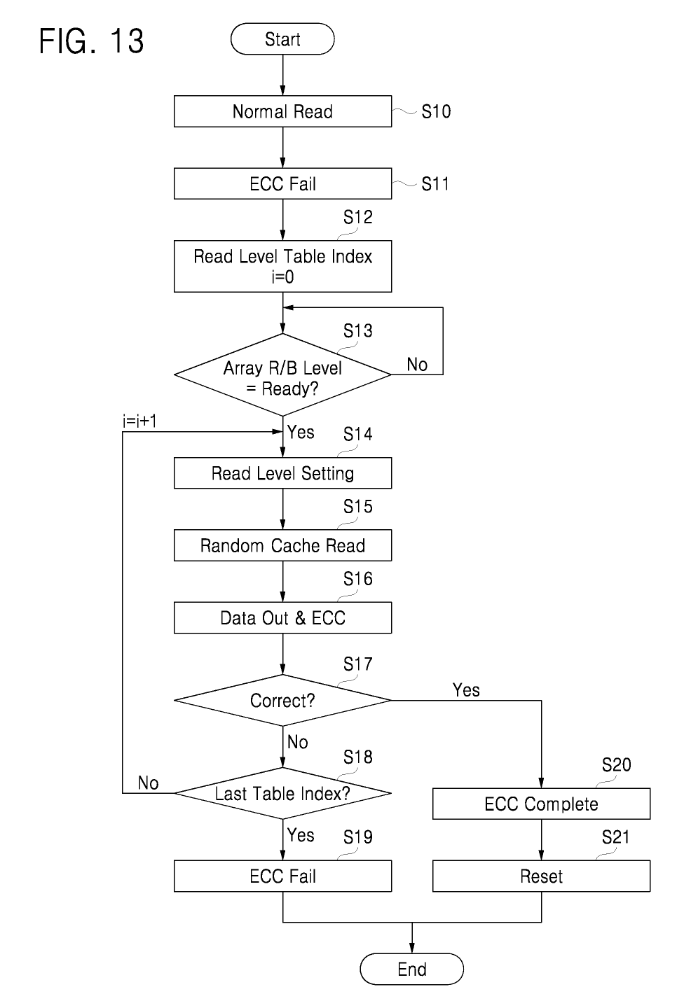

FIG. 13 is a flowchart of a method of reading according to an embodiment. The method of FIG. may use the memory system 20 illustrated in FIG. 1 according to some embodiments.

Referring to FIG. 13, the memory controller 100 sends a normal read command to the non-volatile memory device 200 and, in response thereto, receives first read data from the non-volatile memory device 200 in operation S10. The ECC circuit 140 of the memory controller 100 performs ECC operations on the normal read data. If an ECC fail occurs in operation S11 (e.g., the ECC circuit determines detected errors are uncorrectable), the memory controller 100 starts a read retry operation.

To track the number of read retries, a read retry count or index i is initialized, setting i to 0 in operation S12. A read level corresponding to the read retry count (index) i may be retrieved from the read level table at that time. The index i in the read retry table 115 may identify a read level corresponding to the index i. The array R/B signal is monitored in operation S13 to determine if the memory cell array (e.g., 210) of the non-volatile memory is in a ready state.

If the array R/B signal is “1” or transitions from “0” to “1” when the non-volatile memory device 200 is ready, the memory controller 100 sets the read level in operation S14 to data new level (e.g., by issuing a command to the non-volatile memory device 200 to set a new read level). For example, the read level that is set is based on a predetermined value in the read retry table 115 identified by the count i.

The memory controller 100 sends a RC (random cache) read command to the non-volatile memory device 200 in operation S15. The RC read command may be sent with the address of the page that previously failed the ECC operation in S11.

The RC read command may be a read command for reading only a target page (e.g., with a read retry or a normal read) instead of sequentially reading multiple pages from the memory cell array 210 of the non-volatile memory device 200.

In response to the RC read command, the non-volatile memory device 200 performs a read operation for the target page. This may include reading the target page in the memory cell array 210 and storing the read page in the cache register 221-11. In addition, the non-volatile memory 200 may transfer data (such as previously read data as described in any one of the other embodiments described herein) from the cache register 221-11 to the data register 221-1.

While the retry data is being read and stored in the cache register 221-11, the non-volatile memory device 200 may output the previous read data now stored in the data register 221-1 to the memory controller 100 and the memory controller 100 performs ECC on the previous read data in operation S16. In one alternative embodiment, as described above, if the data stored in the data register 221-1 is previously normally read data (e.g., not read retry data), this data may be ignored by the memory controller 200 (e.g., the memory controller may fail to latch this data or latch it and discard it) or the non-volatile memory device 200 may fail to transmit this normally read data.

If the ECC is successfully completed in operations S17, the ECC operations are completed in step S20 (e.g., the ECC operation determines which of the bits are erroneous bits, corrects the same and outputs the corrected data), the memory controller 100 transmits a reset command to the non-volatile memory device 200 in operation S21 to terminate the read retry operation. The reset command may also reset the read levels to normal read levels in the non-volatile memory device 200. However, if the ECC fails or otherwise determines errors in the retry data are uncorrectable in operation S17, the index (retry count) i is increased in operation S18 and a read retry is repeated (including steps S14, S15, S16 and S17) with a new read level corresponding to the increased index (retry count) i until the ECC is successfully completed or until a certain number of read retries has been attempted but with no correct ECC results being obtained. For example, when the index (read retry count) i reaches a value corresponding to the last read level entry in the read retry table 115 it is determined that the overall ECC operation fails in operation S19, the read retry operation ends. Other decisions may be used in S19 to determine the overall ECC operation has failed, such as when the index (read retry count) i reaches a predetermined value (such as set by a manufacturer during design or during manufacturing, e.g., via setting a value in a register by cutting fuses with a laser). The predetermined value may also be programmable by the host 10, which may allow a user to set the number or read retry attempts. After an overall ECC operation has been determined to fail in operation S19, the block storing the target page subject to the read retry operation may be identified as a bad block. If such block is identified as a bad block, other pages in the block may be read and transferred to another empty block and an address translation table in the memory controller 100 may be updated so that subsequent accesses to the moved pages access these pages from the new block. The block identified as a bad block may be removed from future use in the non-volatile memory by virtue of it being identified as a bad block (and a bad block table in the non-volatile memory and/or memory controller (such as RAM 110) being updated).

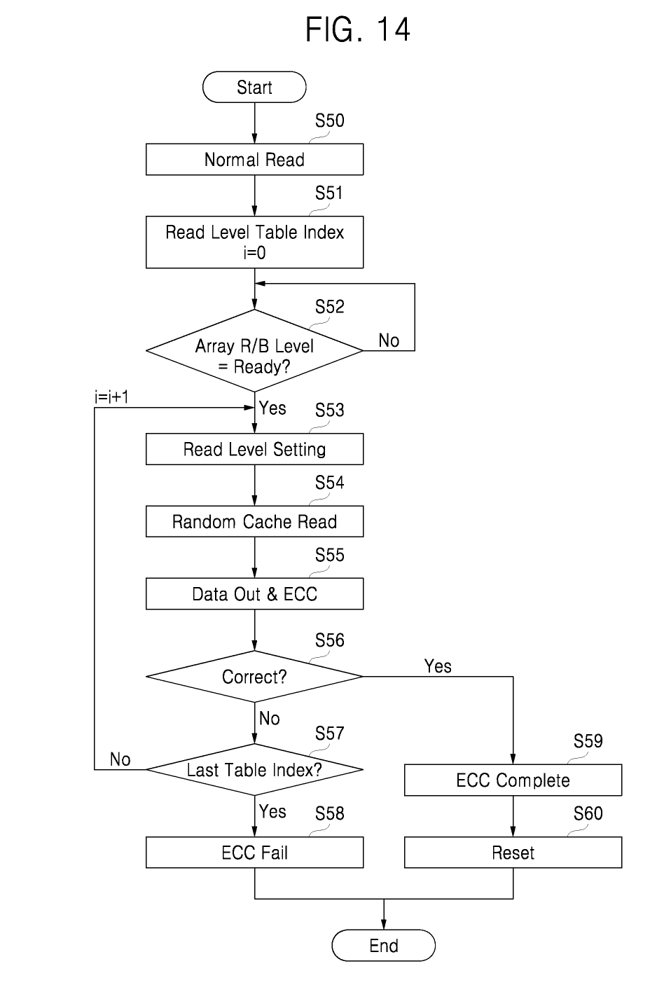

FIG. 14 is a flowchart of a method of controlling data reading using the memory system 20 illustrated in FIG. 1 according to other embodiments of the present invention.

Referring to FIG. 14, the memory controller 100 sends a normal read command to the non-volatile memory device 200 and the non-volatile memory device 200 reads data from a target page in the memory cell array 210 in response to the normal read command in operation S50.

Different from the embodiments illustrated in FIG. 13, the memory controller 100 starts a read retry operation of the non-volatile memory device 200 regardless of an ECC operation and in this embodiment, prior to the start and prior to the completion of the ECC operation.

To reset the number of read retries, i.e., a read retry count and a read level corresponding to the read retry count, an index in the read retry table 115 is initialized in operation S51. It is monitored whether an array R/B signal is in a ready state in operation S52 to determine whether a read operation can be performed.

If the array R/B signal is “1” or transitions from “0” to “1” when the non-volatile memory device 200 is ready, the memory controller 100 sets the read level to a new read level in operation S53. For example, the read level is set based on a command containing information reflecting a predetermined value in the read retry table 115. If subsequent read retry operations are performed, the index i is increased by 1 and the read level is set to a new level based on the new index i.

The memory controller 100 sends a RC read command to the non-volatile memory device 200 in operation S54 with an address of the target page to be subject to the read retry operation.

In response to the RC read command, the non-volatile memory device 200 transmits the data that has been read previously and temporarily stored in the cache register 221-11 to the data register 221-1 and temporarily stores retry data, which has been read from the target page in the memory cell array 210 through the read retry, in the cache register 221-11.

While the retry data is being read and stored in the cache register 221-11, the non-volatile memory device 200 may output the previous read data transmitted to the data register 221-1 to the memory controller 100 and the ECC circuit 140 and ECC operations may be performed on the previous read data in operation S55.

If the ECC is successfully completed in operations S56 and S59, the memory controller 100 transmits a reset command to the non-volatile memory device 200 in operation S60 to terminate the read retry operation.

However, if the ECC fails in operation S56, the index in the read retry table 115 is increased in operation S57 and a read retry is repeated until the ECC is successfully completed. At this time, when the index is the last one in the read retry table 115 and the ECC fails in operation S58, the read retry operation ends. This may include resetting read levels to default levels. It may also include flushing data stored in cache register 221-11 and/or the data register 221-1 or otherwise allowing the non-volatile memory to discard such data in future operations (such as writing new data over data in these registers without sending the data to an device external to the non-volatile memory 200).

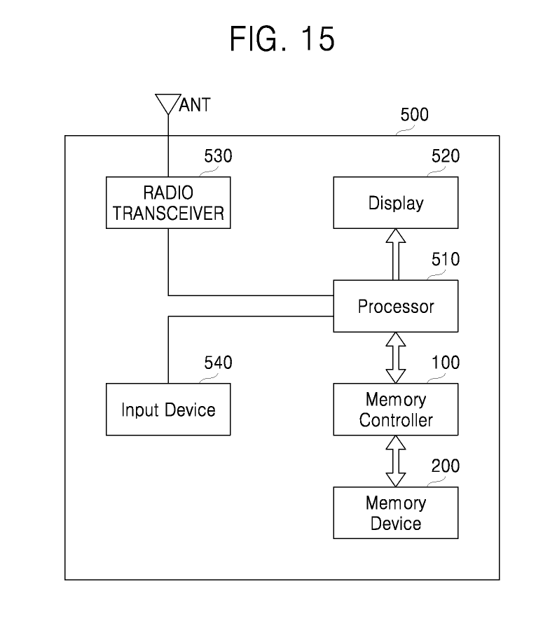

FIG. 15 is a data processing system, which includes the memory system shown in FIG. 1, according to an exemplary embodiment. Referring to FIG. 15, a data processing system 500 may be embodied in a cellular phone, a smart phone, a personal digital assistant (PDA) or a radio communication device.

The data processing system 500 includes the memory device 200 and the memory controller 100 controlling an operation of the memory device 200. The memory controller 100 may control data access operations of the memory device 200, e.g., a program (or write) operation, an erase operation and/or a read operation, according to the control of a processor 510. A program-verify operation may be included as a part of a program operation.

Page data programmed in the memory device 200 may be displayed through a display 520 according to a control of the processor 510 and the memory controller 100.

The radio transceiver 530 may transmit or receive a radio signal through an antenna ANT. For example, the radio transceiver 530 may convert a radio signal received through an antenna ANT into a signal which may be processed by the processor 510. Accordingly, the processor 510 may process a signal output from the radio transceiver 530 and transmit a processed signal to the memory controller 100 or the display 520. The memory controller 100 may program a signal processed by the processor 510 in the memory device 200. Moreover, the radio transceiver 530 may convert a signal output from the processor 510 into a radio signal and output a converted radio signal to an external device through an antenna ANT.

An input device 540 is a device which may input a control signal for controlling an operation of the processor 510 or data to be processed by the processor 510. It may be embodied in a pointing device such as a touch pad and a computer mouse, a keypad or a keyboard.

The processor 510 may control an operation of the display 520 so that data output from the memory controller 100, data output from the radio transceiver 530 or data output from the input device 540 may be displayed through the display 520. According to an example embodiment, the memory controller 100 controlling an operation of the memory device 200 may be embodied as a part of the processor or as a chip separate from the processor.

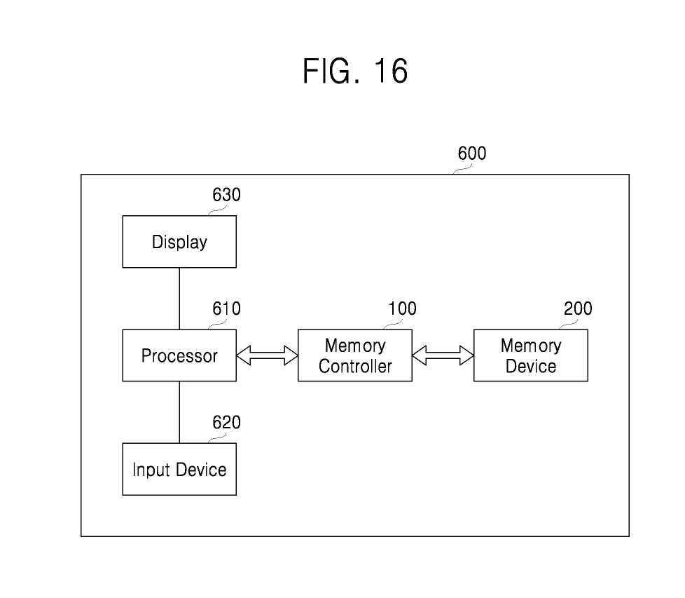

FIG. 16 is a data processing system, which includes the memory system shown in FIG. 1, according to another exemplary embodiment. Referring to FIG. 16, a data processing system 600 may be embodied in a personal computer (PC), a tablet PC, a net-book, an e-reader, a personal digital assistant (PDA), a portable multimedia player (PMP), a MP3 player or a MP4 player.

The data processing system 200 includes the memory device 200 and the memory controller 100 controlling a data processing operation of the memory device 200. A processor 610 may display data stored in the memory device 200 through a display 230 according to data input through an input device 620. For example, the input device 620 may be embodied in a pointing device such as a touch pad or a computer mouse, a keypad or a keyboard.

The processor 610 may control a general operation of the memory system 200 and an operation of the memory controller 100. According to an example embodiment, the memory controller 100 controlling an operation of the memory device 200 according to an example embodiment may be not only embodied as a part of the processor 610 but also embodied in a chip separate from the processor 610.

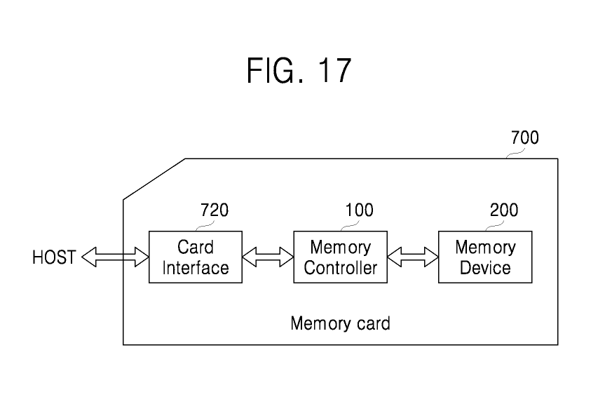

FIG. 17 is a data processing system, which includes the memory system shown in FIG. 1, according to still another exemplary embodiment. Referring to FIG. 17, a data processing system 700 may be embodied in a memory card or a smart card. The data processing system 700 includes the memory device 200, the memory controller 100 and a card interface 720.

The memory controller 100 may control data exchange between the memory device 200 and the card interface 720. According to an example embodiment, the card interface 720 may be a secure digital (SD) card interface or a multi-media card (MMC) interface, however, it is not restricted thereto.

The card interface 720 may allow for the exchange of data between a host and the memory controller 100 according to protocol of a host. According to an example embodiment, the card interface 720 may support a universal serial bus (USB) protocol and an interchip (IC)-USB protocol. Here, a card interface may mean hardware supporting a protocol used in a host, software configuring the hardware, and/or a signal transmission system.

When the data processing system 700 is connected to a host such as a PC, a tablet PC, a digital camera, a digital audio player, a cellular phone, console video game hardware or a digital set-top box, the host may perform data communication with the memory device 200 through the card interface 720 and the memory controller 100.

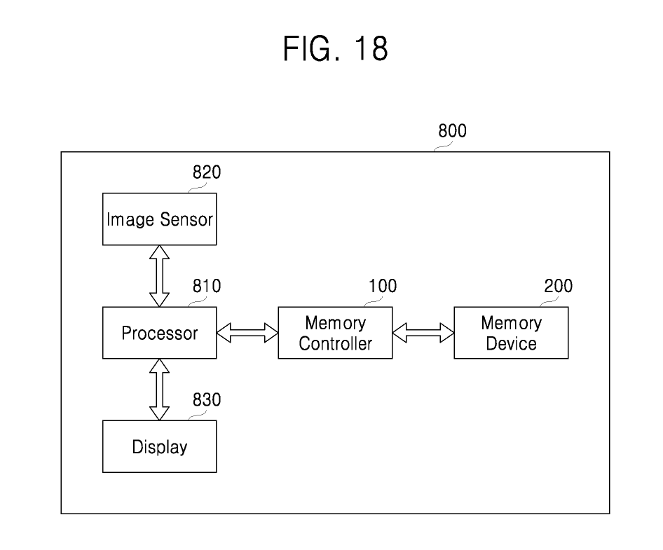

FIG. 18 is a data processing system, which includes the memory system shown in FIG. 1, according to still another exemplary embodiment. Referring to FIG. 18, a data processing system 800 may be embodied in an image processing device, e.g., a digital camera or a digital camera-equipped cellular phone. The data processing system 800 includes the memory device 200 and the memory controller 100 controlling a data processing operation of the memory device 200, e.g., a program operation, an erase operation or a read operation. An image sensor 820 of the memory system 400 converts an optical image into digital signals and converted digital signals are transmitted to a processor 810 or the memory controller 100. According to a control of the processor 810, the converted digital signals may be displayed through a display 830 or stored in the memory device 200 through the memory controller 100.

In addition, data stored in the memory device 200 is displayed through the display 830 according to a control of the processor 810 and the memory controller 100. According to an example embodiment, the memory controller 100 controlling an operation of the memory device 200 may be not only embodied as a part of the processor 810 but also embodied in a chip separate from the processor 810.

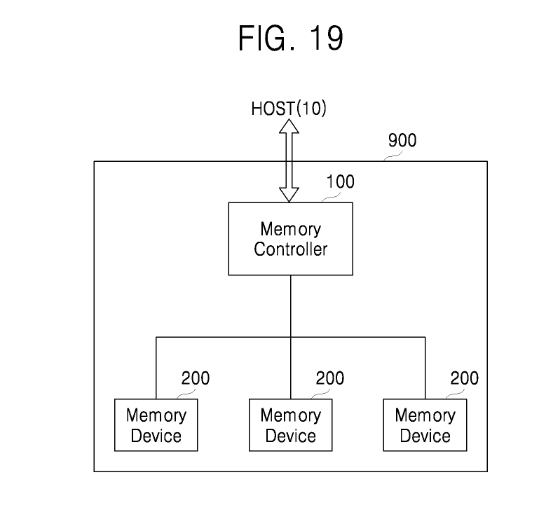

FIG. 19 is a data processing system, which includes the memory system shown in FIG. 1, according to still another exemplary embodiment. Referring to FIG. 19, a data processing system 900 may be embodied in a data storage device such as a solid state drive (SSD).

The data processing system 900 may include a plurality of memory devices 200, the memory controller controlling a data processing operation of each of the plurality of memory devices 200. The data processing system 900 may be embodied in a memory module.

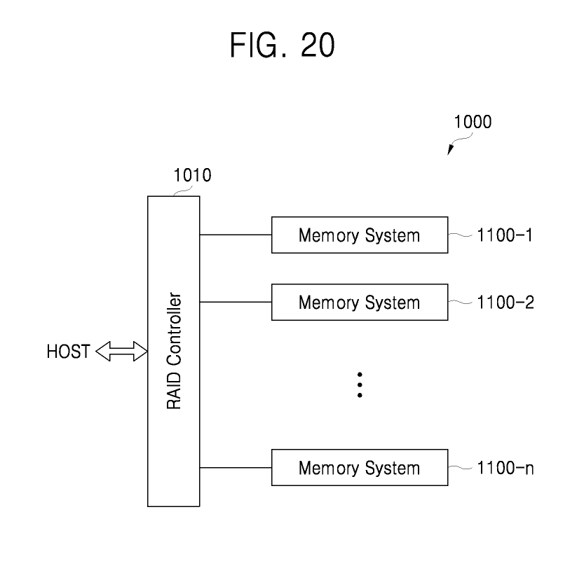

FIG. 20 is a block diagram of a data storage device 1000 including the data processing system 900 illustrated in FIG. 19. Referring to FIGS. 19 and 20, the data storage device 1000 may be implemented as a redundant array of independent disks (RAID) system. The data storage device 1000 includes a RAID controller 1010 and a plurality of memory systems 1100-1 through 1100-n where “n” is a natural number.

Each of the memory systems 1100-1 through 1100-n may be data processing system 900 illustrated in FIG. 19. The data processing systems 1100-1 through 1100-n may form a RAID array. The data storage device 1000 may be a PC or an SSD.

During a program operation, the RAID controller 1010 may transmit program data output from a host to at least one of the memory systems 1100-1 through 1100-n according to a RAID level in response to a program command received from the host. During a read operation, the RAID controller 1010 may transmit to the host data read from at least one of the memory systems 1100-1 through 1100-n in response to a read command received from the host.

In the embodiments described herein, a level set command may be and/or other commands may be sent by a memory controller (or other external source) to the non-volatile memory 200 to initiate a read retry. However, it is contemplated that all such actions by the memory controller may not be necessary to implement the read retry operations. All of the embodiments described herein may be modified such that the non-volatile memory device may automatically modify a read level (e.g., by referring to an internal register which indicates a difference (percentage or fixed level), such as a programmable mode set register, or by referring to a lookup table portion within the non-volatile memory array) and automatically initiate a new read operation of the target page without any command from the memory controller 100. These level setting and read retry processes may be repeated (without an external command) until the memory controller 100 issues a command (or communicates with a status signal) to end the repeating read retries. Alternatively, a fixed number of read retries may be automatically performed without an external command from the memory controller 100. In these alternative embodiments, a total read retry time may further be reduced by eliminating time communicate (e.g., give commands) to the non-volatile memory 200. In addition, it may free up a bus between the memory controller 100 and non-volatile memory 200 that may be shared with other devices.

In addition, all of the embodiments described herein may be modified such that the non-volatile memory determines whether or not to output new read retry data or discard the new read retry data. For example, the non-volatile memory may compare a page or read data that was read from a target page in a read retry operation (e.g., stored in cache register 221-11 to 221-m1) with data previously read from the target page. If the data is the same, the non-volatile memory may discard the data read in the read retry operation, change the read level to new read level and perform a new read retry operation with the changed read level. The new read level may be determined by the non-volatile memory, or may be sent from the memory controller 100 to the non-volatile memory upon receiving a status signal from the non-volatile memory 200. Determining whether the new read retry data is the same with that previously sent to the memory controller 100 may be implemented by performing an exclusive or (XOR) between bits of the cache register 221-11 to 221-m1) with corresponding bits of the page of read data stored in the data register 221-1 to 221-m (already sent to the memory controller) (which would generate a 1 if a bit changed or a 0 if not changed) with an OR operation on the total outputs of the XOR gates (which would generate a 1 if any bit of the page changed). Alternatively, determining whether the newly read retry data is the same with that previously read from the target page may be done with circuitry (e.g., circuitry of page register & S/A 220) which indicates if the new read retry operation changes a latch status of any latch of cache register 221-11 to 221-m1. These alternative embodiments may further reduce a total read retry time by eliminating a time to send data out to the memory controller, as well free up a bus between the memory controller 100 and the non volatile memory device 200 (such as I/O0 to I/O7). In addition, power savings may be achieved by eliminating the data transfer operation and the ECC operation by the memory controller. The disclosure also contemplates variations to the all embodiments described herein where the memory controller 100 determines that data received from the non volatile memory device 200 is the same as that previously received, and thus skips a second ECC operation on the same data just received to thereby save power.

As described above, according to some embodiments of the present invention, a period of time during which at least two read retries are performed is saved, thereby reducing a total read retry duration. When the total read retry duration is reduced, the reliability and/or the read speed of a non-volatile memory device may be increased, thereby increasing the performance of a memory system.

While the present invention has been particularly shown and described with reference to exemplary embodiments thereof, it will be understood by those of ordinary skill in the art that various changes in forms and details may be made therein without departing from the spirit and scope of the present invention as defined by the following claims. It should be noted that unless the claims use the word “means” applicant does not intend for the claims to be interpreted as a “means plus function” claim.

What is claimed is:

1. A method of operating a nonvolatile memory
issuing a first read command that commands the nonvolatile memory to perform a first read of a first page of the nonvolatile memory;
receiving a first read page of data resulting from the first read;
determining that the first read page of data resulting from the first read has errors that are not to be corrected by an error correction circuit;
in response to the determining step, issuing a second read command that commands the non-volatile memory to perform a second read of the first page again with an operating parameter different than an operating parameter used in performing the first read;
receiving a second read page of data resulting from the second read;
analyzing whether the second read page of data resulting from the second read has errors that are not to be corrected by an error correction circuit; and
before the analyzing step is complete, issuing a third read command that commands the non-volatile memory to perform a third read of the first page again with an operating parameter different than an operating parameter used in performing the first read and different from an operating parameter used in performing the second read.

2. The method of claim 1, wherein the third read command is issued before the step of receiving the second read page of data resulting from the second read is complete.

3. The method of claim 1, wherein the third read command is issued before receiving any data of the second read page of data resulting from the second read.

4. The method of claim 1,
wherein the first page is stored in a first physical page, and
wherein the operating parameters represents a magnitude of a read reference voltage used by the nonvolatile memory to determine memory cell data for each of multiple memory cells of the first physical page.

5. The method of claim 1,
wherein the first page is stored in a first physical page,
wherein the nonvolatile memory is a NAND flash memory, and
wherein the operating parameters represents a magnitude of a read reference voltage applied to a word line of the first physical page of the nonvolatile memory to determine memory cell data for each of multiple memory cells of the first physical page.

6. The method of claim 1,
wherein the first page is stored in a first physical page,
wherein the nonvolatile memory is a multi-level cell (MLC) NAND flash memory, and
wherein the second read command and the third read command each command the non-volatile flash memory to read the MLC NAND flash memory with two new read reference voltages that are sequentially applied to the word line of the first physical page during the corresponding read operation.

7. The method of claim 1, wherein each of the second read command and third read command are a read retry command.

8. The method of claim 7, wherein each of the second read command and third read command are a read retry command and include a value representing the corresponding operating parameter.

9. The method of claim 7,
wherein a value representing the corresponding operating parameter associated with the second read and a value representing the corresponding the operating parameter used with the third read are retrieved from a look-up table.

10. The method of claim 9, wherein a memory controller issues the first, second and third commands and comprises the look-up table.

11. The method of claim 9, wherein the nonvolatile memory comprises the look-up table.

12. The method of claim 7, wherein each of the second and third read commands do not comprise any address information.

13. The method of claim 1, further comprising:
prior to issuing the second read command, issuing a first level set command that is operative to set in the nonvolatile memory the operating parameter used with the second read, and
prior to issuing the third read command, issuing a second level set command that is operative to set in the nonvolatile memory the operating parameter used with the third read.

14. The method of claim 13, further comprising determining that a memory array of the nonvolatile memory is not performing a read operation prior to issuing each of the first level set command and second level set command.

15. A method of operating a NAND flash memory, comprising:
a first reading of a first page of the NAND flash memory to obtain a first read page of data, and
then, prior to completion of an error correction operation on the first page of read data, issuing a read command, the read command causing a second reading of the first page with at least one adjusted read voltage.

16. A method of operating a nonvolatile memory, comprising:
a first reading of a page of the nonvolatile memory with a first read operation parameter to obtain a first read page of data and storing the first read page of data in a first register of the nonvolatile memory;
transferring the first read page of data from the first register to a second register of the nonvolatile memory;
transferring the first read page of data from the second register to the memory controller; and
while transferring the first read page of data from the second register to the memory controller, a second reading of the page of data again using a second read operation parameter different from the first read operation parameter.

17. The method of claim 16, wherein the first and second read operation parameters are first and second read reference voltages, respectively, used by the nonvolatile memory to determine memory cell data for each of multiple memory cells storing the page for the respective reading operations.

18. The method of claim 17, wherein the nonvolatile memory is a NAND flash memory and the page is stored in a first physical page of the NAND flash memory, and wherein the method further comprises:
applying the first read reference voltage to a word line of the first physical page during the first reading to determine memory cell data for each of multiple memory cells of the first physical page; and
applying the second read reference voltage to the word line of the first physical page during the second reading to determine memory cell data for each of multiple memory cells of the first physical page.

19. The method of claim 18, wherein the nonvolatile memory is a multi-level cell (MLC) NAND flash memory and the page is stored in a first physical page of the NAND flash memory, and wherein the method further comprises:
applying a first set of read reference voltages including the first read reference voltage to a word line of the first physical page during the first reading to determine memory cell data for each of multiple memory cells of the first physical page; and
applying a second set of read reference voltages including the second read reference voltage to a word line of the first physical page during the second reading to determine memory cell data for each of multiple memory cells of the first physical page,
wherein the second set of read reference voltages are different from the first set of read reference voltages.

20. The method of claim 16, further comprising:
receiving a read retry command which instructs the nonvolatile memory device to perform the second reading.

21. The method of claim 20, wherein the read retry command includes a value representing the second read operation parameter.

22. The method of claim 20, wherein the read retry command does not comprise any address information.

23. The method of claim 16, further comprising:
receiving a first level set command that is operative to set in the nonvolatile memory the second read operation parameter.

24. The method of claim 16, further comprising:
outputting a flag signal to a memory controller in response to the nonvolatile memory performing the first reading.

25. A method of operating a NAND flash memory, comprising:
a first reading of a first page of the NAND flash memory to obtain a first read page of data, and
then, prior to completion of an error correction operation on the first read page of data, issuing a read command, the read command causing a second reading of the first page with at least one adjusted read voltage.

26. The method of claim 25, wherein the issuing the read command is issued before receiving all of the first read page of data resulting from the first reading.

27. The method of claim 25, wherein the issuing the read command is issued before receiving any of the first read page of data resulting from the first reading.

28. The method of claim 25, wherein the read command is a read retry command.

29. A nonvolatile memory device comprising:
a memory array including a first physical page;
a first data register;
a second data register; and
a control circuit, configured to perform a first reading of a page to obtain a first read page, to store the first read page into the first data register, transfer the first read page of data resulting from the first reading from the first data register to the second data register, to perform a second reading of the page when the first read page of data resulting from the first reading is stored in the second data register, and to transfer the page of data resulting from the first reading from the second data register to an external source.

30. A nonvolatile memory device comprising:
a memory array;
a command circuit configured to receive a read command and to initiate a read operation of the memory array in response to the read command;
a control circuit configured to assert a first R/B (ready busy) flag to indicate the nonvolatile memory cannot accept additional commands and being responsive to the read operation to assert a second R/B flag to indicate a status of the memory array; and
a data buffer configured to output data from the nonvolatile memory when the second R/B flag indicates a busy status of the memory array in response to the read operation.

31. The nonvolatile memory device of claim 30,
wherein the a control circuit is responsive to a read status command received from an external memory controller to assert the first R/B flag and the second R/B flag in response.

32. A memory controller configured to operate a NAND flash memory, comprising:
an interface;
an error correction coding circuit configured analyze a page of data received over the interface to correct bit errors of the page and to determine if the page of data has an uncorrectable error; and
a command circuit configured to generate commands and output the same to the interface, including a first read command to cause a first read of a first page of the NAND flash memory and to receive a first read page over the interface resulting from the first read,
wherein the error correction coding circuit is configured to determine if first read page has an uncorrectable error, and
wherein the command circuit is configured to issue a second read command, prior to completion of a determination operation by the error correction coding circuit to determine whether the first read page of data has an uncorrectable error, the second read command causing a second read of the first page with at least one adjusted read voltage.

33. The memory controller of claim 32, wherein the command circuit is configured to issue the second read command before all of the first read page of data is received over the interface.

34. The memory controller of claim 32, wherein the command circuit is configured to issue the second read command before any of the first read page is received over the interface

35. The memory controller of claim 35, the second read command is a read retry command.

36. A memory card comprising:
a non-volatile memory device comprising a memory cell array which comprises a plurality of pages storing data and an access circuit which comprises a first register temporarily storing data read from the memory cell array in a read operation and a second register receiving data from the cache register and storing the data;
a card interface configured to communicate with a host; and
a memory controller interfaces between the non-volatile memory device and the card interface,
wherein the memory controller is configured to transmit to the non-volatile memory a first read command to read data from a target page among a plurality of pages in the non-volatile memory device, and to transmit a second read command to the non-volatile memory to read data from the target page, and
wherein the memory controller is configured to receive data that has been read in response to the first read command while the non-volatile memory device is reading data from the target page in response to the second read command.
